(19) United States
(12) Patent Application Publication
(10) Pub. No.: US 2023/0335633 A1
(43) Pub. Date: Oct. 19, 2023

(54) WIDE BANDGAP SEMICONDUCTOR DEVICE

(71) Applicant: ROHM CO., LTD., Kyoto-shi, Kyoto (JP)

(72) Inventors: Yuki NAKANO, Kyoto-shi, Kyoto (JP); Yasunori KUTSUMA, Kyoto-shi, Kyoto (JP)

(21) Appl. No.: 18/254,029

(22) PCT Filed: Feb. 3, 2022
(86) PCT No.: PCT/JP2022/004301

§ 371 Date: May 23, 2023

(30) Foreign Application Priority Data
Mar. 18, 2021 (JP) 2021-045115

(51) Int. Cl. H01L 29/78; H01L 23/29; H01L 23/00

(52) U.S. Cl. CPC H01L 29/7806; H01L 29/7813; H01L 23/295; H01L 24/73; H01L 24/48; H01L 29/7825; H01L 24/08; H01L 2224/73215; H01L 2224/48227; H01L 2924/1306; H01L 2924/07802; H01L 2924/12032; H01L 2224/0801

(57) ABSTRACT

A wide bandgap semiconductor device includes a chip that includes a wide bandgap semiconductor and that has a main surface, a main surface electrode arranged on the main surface, and a thermosetting resin that includes a matrix resin and a plurality of fillers and that covers the main surface such as to expose a part of the main surface electrode.

### TECHNICAL FIELD

This application corresponds to Japanese Patent Application No. 2021-045115 filed in the Japan Patent Office on Mar. 18, 2021, the entire disclosure of which is incorporated herein by reference. The present invention relates to a wide bandgap semiconductor device.

### BACKGROUND ART

Patent Literature 1 discloses a semiconductor device that includes a semiconductor substrate, an electrode, and an organic protective layer. The semiconductor substrate is formed of SiC. The electrode is formed on the semiconductor substrate. The organic protective film partially covers the electrode.

### CITATION LIST

### Patent Literature

Patent Literature 1: United States Patent Application No. 2019/0080976 Specification

### SUMMARY OF INVENTION

### Technical Problem

One embodiment provides a wide bandgap semiconductor device that is capable of improving reliability.

### Solution to Problem

One embodiment provides a wide bandgap semiconductor device including a chip that includes a wide bandgap semiconductor and that has a main surface, a main surface electrode arranged on the main surface, and a thermosetting resin that includes a matrix resin and a plurality of fillers and that covers the main surface such as to expose a part of the main surface electrode.

The aforementioned or still other objects, features, and effects of the present invention will be made clear by the description of embodiments with reference to the accompanying drawings.

### BRIEF DESCRIPTION OF DRAWINGS

FIG. 1 is a perspective view showing a wide bandgap semiconductor device according to a first embodiment.

FIG. 2 is a plan view of the wide bandgap semiconductor device shown in FIG. 1.

FIG. 3 is a cross-sectional view taken along line III-III shown in FIG. 2.

FIG. 4 is an enlarged view of region IV shown in FIG. 3.

FIG. 5 corresponds to FIG. 3, and is a cross-sectional view showing a wide bandgap semiconductor device according to a second embodiment.

FIG. 6 corresponds to FIG. 3, and is a cross-sectional view showing a wide bandgap semiconductor device according to a third embodiment.

FIG. 7 corresponds to FIG. 3, and is a cross-sectional view showing a wide bandgap semiconductor device according to a fourth embodiment.

FIG. 8 corresponds to FIG. 3, and is a cross-sectional view showing a wide bandgap semiconductor device according to a fifth embodiment.

FIG. 9 corresponds to FIG. 3, and is a cross-sectional view showing a wide bandgap semiconductor device according to a sixth embodiment.

FIG. 10 is a perspective view showing a wide bandgap semiconductor device according to a seventh embodiment.

FIG. 11 is a plan view of the wide bandgap semiconductor device shown in FIG. 10.

FIG. 12 is a cross-sectional view taken along line XII-XII shown in FIG. 11.

FIG. 13 is a plan view in which region XIII shown in FIG. 11 is shown together with an internal structure.

FIG. 14 is a cross-sectional view taken along line XIV-XIV shown in FIG. 13.

FIG. 15 is an enlarged view of region XV shown in FIG. 12.

FIG. 16 corresponds to FIG. 12, and is a cross-sectional view showing a wide bandgap semiconductor device according to an eighth embodiment.

FIG. 17 corresponds to FIG. 12, and is a cross-sectional view showing a wide bandgap semiconductor device according to a ninth embodiment.

FIG. 18 corresponds to FIG. 12, and is a cross-sectional view showing a wide bandgap semiconductor device according to a tenth embodiment.

FIG. 19 corresponds to FIG. 12, and is a cross-sectional view showing a wide bandgap semiconductor device according to an eleventh embodiment.

FIG. 20 corresponds to FIG. 12, and is a cross-sectional view showing a wide bandgap semiconductor device according to a twelfth embodiment.

FIG. 21 corresponds to FIG. 3, and is a cross-sectional view showing a modification example of a pad electrode.

FIG. 22 is a plan view showing a semiconductor package in which the wide bandgap semiconductor devices according to the first to sixth embodiments are each mounted.

FIG. 23 is a plan view showing a semiconductor package in which the wide bandgap semiconductor devices according to the seventh to twelfth embodiments are each mounted.

FIG. 24 is a perspective view showing a semiconductor package in which the wide bandgap semiconductor devices according to the first to sixth embodiments and the wide bandgap semiconductor devices according to the seventh to twelfth embodiments are each mounted.

FIG. 25 is an exploded perspective view of the semiconductor package shown in FIG. 24.

FIG. 26 is a cross-sectional view taken along line XXVI-XXVI shown in FIG. 24.

### DESCRIPTION OF EMBODIMENTS

The accompanying drawings are schematic views, and are not necessarily strictly shown, and their reduced scales, etc., do not necessarily coincide with each other. Also, the same reference sign is given to a structure corresponding to each structure shown in the accompanying drawings, and a repetitive description of the structure is omitted or simplified. Also, in the following embodiments, a description of a structure that has been given before being omitted or simplified is applied to a corresponding structure a description of which has been omitted or simplified.

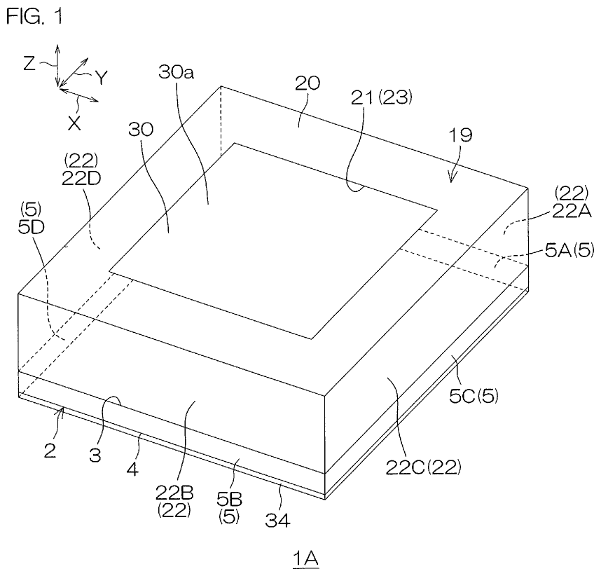

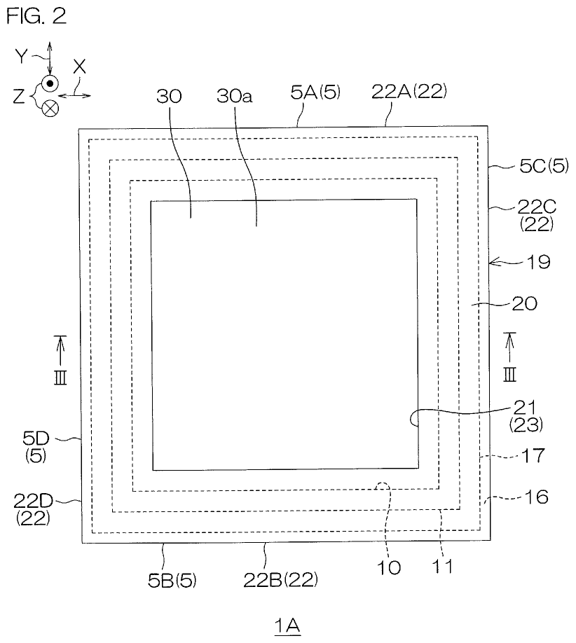

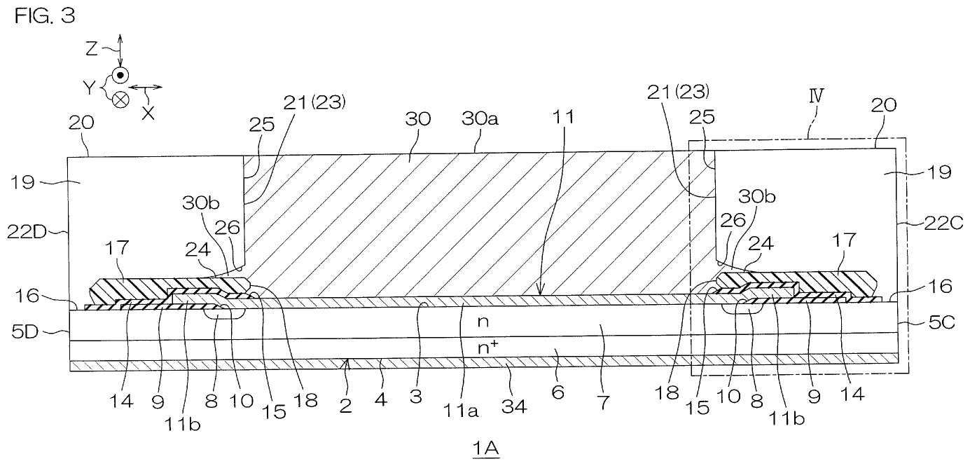

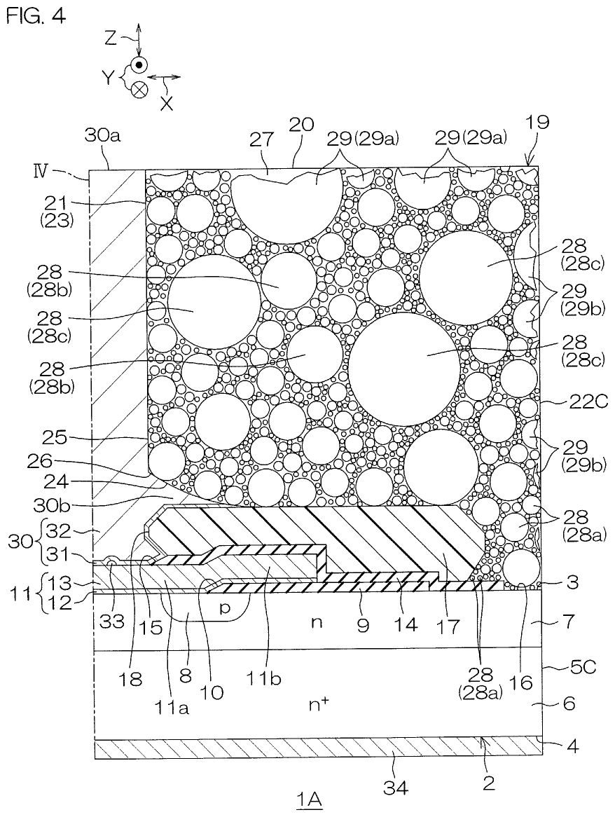

FIG. 1 is a perspective view showing a wide bandgap semiconductor device 1A according to a first embodiment. FIG. 2 is a plan view of the wide bandgap semiconductor device 1A shown in FIG. 1. FIG. 3 is a cross-sectional view taken along line III-III shown in FIG. 2. FIG. 4 is an enlarged view of region IV shown in FIG. 3.

Referring to FIG. 1 to FIG. 4, the wide bandgap semiconductor device 1A is a semiconductor device including an SBD (Schottky Barrier Diode) that is an example of a functional device. The wide bandgap semiconductor device 1A is constituted of a wide bandgap semiconductor, and includes a chip 2 formed in a hexahedron shape (in detail, rectangular parallelepiped shape). The chip 2 may be referred to as a “semiconductor chip” or a “wide bandgap semiconductor chip.” The wide bandgap semiconductor is a semiconductor that has a bandgap exceeding the bandgap of Si (silicon).

In this embodiment, the chip 2 is a SiC chip constituted of a hexagonal SiC (silicon carbide) monocrystal that is an example of the wide bandgap semiconductor. In other words, the wide bandgap semiconductor device 1A is a SiC semiconductor device. The hexagonal SiC monocrystal has a plurality of polytypes including a 2H (Hexagonal)-SiC monocrystal, a 4H-SiC monocrystal, a 6H-SiC monocrystal, etc. In this embodiment, an example in which the chip 2 is constituted of a 4H-SiC monocrystal is shown, and yet other polytypes are not excluded.

The chip 2 has a first main surface 3 on one side, a second main surface 4 on the other side, and a side surface 5 that connects the first main surface 3 and the second main surface 4 together. The first main surface 3 and the second main surface 4 are each formed in a quadrangular shape in a plan view seen from their normal directions Z (hereinafter, referred to simply as a “plan view”). Preferably, the second main surface 4 is constituted of a ground surface having grinding marks.

The side surface 5 includes first to fourth side surfaces 5A to 5D. The first side surface 5A and the second side surface 5B extend in a first direction X along the first main surface 3, and face a second direction Y that intersects (in detail, perpendicularly intersects) the first direction X. The third side surface 5C and the fourth side surface 5D extend in the second direction Y, and face the first direction X. Preferably, the side surface 5 (first to fourth side surfaces 5A to 5D) is a ground surface having grinding marks. The chip 2 may have a thickness of not less than 10 μm and not more than 250 μm with respect to the normal direction Z. Preferably, the thickness of the chip 2 is equal to or less than 80 μm. Particularly preferably, the thickness of the chip 2 is equal to or less than 40 μm.

The wide bandgap semiconductor device 1A includes an n-type (first conductivity type) first semiconductor region 6 formed in a region on the second main surface 4 side in the chip 2. The first semiconductor region 6 is formed as a layer extending along the second main surface 4, and is exposed from the second main surface 4 and from the first to fourth side surfaces 5A to 5D. The first semiconductor region 6 may have a thickness of not less than 5 μm and not more than 200 μm with respect to the normal direction Z. Preferably, the thickness of the first semiconductor region 6 is equal to or less than 50 μm. Particularly preferably, the thickness of the first semiconductor region 6 is equal to or less than 20 μm.

The wide bandgap semiconductor device 1A includes an n-type second semiconductor region 7 formed in a region on the first main surface 3 side in the chip 2. The second semiconductor region 7 has an n-type impurity concentration lower than the first semiconductor region 6, and is electrically connected to the first semiconductor region 6. The second semiconductor region 7 is formed as a layer extending along the first main surface 3, and is exposed from the first main surface 3 and from the first to fourth side surfaces 5A to 5D.

The second semiconductor region 7 may have a thickness of not less than 5 μm and not more than 50 μm with respect to the normal direction Z. Preferably, the thickness of the second semiconductor region 7 is equal to or less than 30 μm. Particularly preferably, the thickness of the second semiconductor region 7 is equal to or less than 20 μm. Preferably, the thickness of the second semiconductor region 7 exceeds the thickness of the first semiconductor region 6.

In this embodiment, the first semiconductor region 6 is constituted of a wide bandgap semiconductor substrate (in detail, SiC semiconductor substrate). In this embodiment, the second semiconductor region 7 is constituted of a wide bandgap semiconductor epitaxial layer (in detail, SiC epitaxial layer). In other words, the chip 2 has a laminated structure including a wide bandgap semiconductor substrate and a wide bandgap semiconductor epitaxial layer. The wide bandgap semiconductor substrate forms the second main surface 4 and parts of the first to fourth side surfaces 5A to 5D. The wide bandgap semiconductor epitaxial layer forms the first main surface 3 and parts of the first to fourth side surfaces 5A to 5D.

The wide bandgap semiconductor device 1A includes a p-type (second conductivity type) guard region 8 formed at a surface layer portion of the first main surface 3. A p-type impurity of the guard region 8 may be activated, or may not be activated. The guard region 8 is formed at a surface layer portion of the second semiconductor region 7 at an interval inward from a peripheral edge (first to fourth side surfaces 5A to 5D) of the first main surface 3. In this embodiment, the guard region 8 is formed in an annular shape (in this embodiment, quadrangular annular shape) surrounding an inward portion of the first main surface 3 in a plan view. Hence, the guard region 8 is formed as a guard ring region. The guard region 8 has an inner edge portion on the inward portion side of the first main surface 3 and an outer edge portion on the peripheral edge side of the first main surface 3.

The wide bandgap semiconductor device 1A includes a first inorganic insulating film 9 covering the first main surface 3. The first inorganic insulating film 9 covers a region between the peripheral edge of the first main surface 3 and the guard region 8. In detail, the first inorganic insulating film 9 covers the first main surface 3 and the outer edge portion of the guard region 8, and exposes the inward portion of the first main surface 3 and the inner edge portion of the guard region 8. In this embodiment, the first inorganic insulating film 9 is formed in an annular shape (in this embodiment, quadrangular annular shape) surrounding the inward portion of the first main surface 3 in a plan view.

The first inorganic insulating film 9 has an inner wall on the inward portion side of the first main surface 3 and an outer wall on the peripheral edge side of the first main surface 3. The inner wall of the first inorganic insulating film 9 defines a contact opening 10 that exposes the second semiconductor region 7 and the inner edge portion of the guard region 8 in the inward portion of the first main surface 3. The contact opening 10 is formed in a quadrangular shape along the guard region 8 in a plan view. The outer wall of the first inorganic insulating film 9 is formed at an interval inward from the peripheral edge of the first main surface 3, and exposes the second semiconductor region 7 in the peripheral edge portion of the first main surface 3.

As a matter of course, the first inorganic insulating film 9 may cover the whole area of the region between the peripheral edge of the first main surface 3 and the guard region 8. In this case, the first inorganic insulating film 9 has an outer wall continuous to the side surface 5 (first to fourth side surfaces 5A to 5D) of the chip 2. Preferably, the outer wall of the first inorganic insulating film 9 is constituted of a ground surface having grinding marks. Preferably, the outer wall of the first inorganic insulating film 9 forms a single ground surface together with the side surface 5 (first to fourth side surfaces 5A to 5D) of the chip 2.

The first inorganic insulating film 9 includes at least one among a silicon oxide film, a silicon nitride film, and a silicon oxynitride film. Preferably, the first inorganic insulating film 9 has a single layer structure constituted of a silicon oxide film. Particularly preferably, the first inorganic insulating film 9 includes a silicon oxide film constituted of an oxide of the chip 2. The first inorganic insulating film 9 may have a thickness of not less than 10 nm and not more than 500 nm.

The wide bandgap semiconductor device 1A includes a first main surface electrode 11 covering the first main surface 3. The first main surface electrode 11 is formed on the first main surface 3 at an interval inward from the peripheral edge of the first main surface 3. In this embodiment, the first main surface electrode 11 is formed in a quadrangular shape having four sides parallel to the peripheral edge of the first main surface 3 in a plan view. The first main surface electrode 11 is electrically connected to the second semiconductor region 7 and to the inner edge portion of the guard region 8 in the inward portion of the first main surface 3.

In detail, the first main surface electrode 11 has a main body portion 11a positioned in the contact opening 10 and a lead-out portion 11b led out from the main body portion 11a onto the first inorganic insulating film 9. The main body portion 11a forms a Schottky junction with the second semiconductor region 7 (first main surface 3). The lead-out portion 11b is formed at an interval inward from the outer wall of the first inorganic insulating film 9, and faces the outer edge portion of the guard region 8 and the second semiconductor region 7 with the first inorganic insulating film 9 between the outer edge portion of the guard region 8 and the second semiconductor region 7. The first main surface electrode 11 may have a thickness of not less than 0.5 μm and not more than 11 μm.

Referring to FIG. 4, the first main surface electrode 11 has a laminated structure including a first main surface electrode film 12 and a second main surface electrode film 13 that are laminated in that order from the chip 2 side. In this embodiment, the first main surface electrode film 12 includes a Ti-based metal film. The first main surface electrode film 12 may have a single layer structure constituted of a Ti film or a TiN film. The first main surface electrode film 12 may have a laminated structure including a Ti film and a TiN film in arbitrary order. The first main surface electrode film 12 may have a thickness of not less than 10 nm and not more than 1 μm.

The second main surface electrode film 13 is constituted of a Cu-based metal film or an Al-based metal film. The second main surface electrode film 13 may include at least one among a pure Cu film (Cu film whose purity is 99% or more), a pure Al film (Al film whose purity is 99% or more), an AlCu alloy film, an AlSi alloy film, and an AlSiCu alloy film. In this embodiment, the second main surface electrode film 13 is constituted of an Al-based metal film. The second main surface electrode film 13 has a thickness exceeding the thickness of the first main surface electrode film 12. The thickness of the second main surface electrode film 13 may be not less than 0.5 μm and not more than 10 μm.

The wide bandgap semiconductor device 1A includes a second inorganic insulating film 14 that covers the first main surface electrode 11. In detail, the second inorganic insulating film 14 covers the first inorganic insulating film 9 and a peripheral edge portion of the first main surface electrode 11, and exposes an inward portion of the first main surface electrode 11. In more detail, the second inorganic insulating film 14 covers the lead-out portion 11b of the first main surface electrode 11, and exposes the main body portion 11a. The second inorganic insulating film 14 may cover a part of the main body portion 11a. The second inorganic insulating film 14 is led out onto the peripheral edge portion of the first main surface 3 from above the first inorganic insulating film 9, and directly covers the second semiconductor region 7.

In this embodiment, the second inorganic insulating film 14 is formed in an annular shape (in this embodiment, quadrangular annular shape) surrounding the inward portion of the first main surface 3 in a plan view. The second inorganic insulating film 14 has an inner wall on the inward portion side of the first main surface electrode 11 and an outer wall on the peripheral edge side of the first main surface 3. The inner wall of the second inorganic insulating film 14 defines a first opening 15 that exposes the inward portion (main body portion 11a) of the first main surface electrode 11. The first opening 15 is formed in a quadrangular shape along the peripheral edge of the first main surface electrode 11 in a plan view.

The outer wall of the second inorganic insulating film 14 is formed at an interval inward from the peripheral edge of the first main surface 3, and defines a dicing street 16 that exposes the peripheral edge portion of the first main surface 3. As a matter of course, the outer wall of the second inorganic insulating film 14 may be continuous to the side surface 5 (first to fourth side surfaces 5A to 5D) of the chip 2. Preferably, in this case, the outer wall of the second inorganic insulating film 14 is constituted of a ground surface having grinding marks. Preferably, the outer wall of the second inorganic insulating film 14 forms a single ground surface together with the side surface 5 (first to fourth side surfaces 5A to 5D) of the chip 2.

The second inorganic insulating film 14 is constituted of an inorganic insulator having a comparatively high density, and has barrier properties (shielding ability) against water (moisture). The second inorganic insulating film 14 includes at least one among a silicon oxide film, a silicon nitride film, and a silicon oxynitride film. Preferably, the second inorganic insulating film 14 includes an insulating material differing from the first inorganic insulating film 9. Preferably, the second inorganic insulating film 14 includes a silicon nitride film. Preferably, the second inorganic insulating film 14 has a thickness less than the thickness of the first main surface electrode 11. The thickness of the second inorganic insulating film 14 may be not less than 0.1 μm and not more than 5 μm.

The wide bandgap semiconductor device 1A includes a photosensitive resin 17 that covers the peripheral edge portion of the first main surface electrode 11. The photosensitive resin 17 may be referred to as a “first organic film” or as a “first organic insulating film.” In this embodiment, the photosensitive resin 17 is formed on the second inorganic insulating film 14, and covers the first main surface electrode 11 with the second inorganic insulating film 14 between the photosensitive resin 17 and the first main surface electrode 11. The photosensitive resin 17 has a rigidity lower than that of the second inorganic insulating film 14. In other words, the photosensitive resin 17 has an elastic modulus smaller than that of the second inorganic insulating film 14, and functions as a cushioning material (protective film) against an external force. The photosensitive resin 17 protects the chip 2, the first main surface electrode 11, the second inorganic insulating film 14, etc.

The photosensitive resin 17 extends as a band along the peripheral edge portion of the first main surface electrode 11 in a plan view. In this embodiment, the photosensitive resin 17 is formed in an annular shape (in detail, quadrangular annular shape) surrounding the inward portion of the first main surface electrode 11 in a plan view, and covers the peripheral edge portion of the first main surface electrode 11 over the entire periphery. In detail, the photosensitive resin 17 covers the lead-out portion 11b of the first main surface electrode 11, and exposes the main body portion 11a. The photosensitive resin 17 may cover a part of the main body portion 11a.

The photosensitive resin 17 has an inner wall on the inward portion side of the first main surface electrode 11 and an outer wall on the peripheral edge side of the first main surface 3. The inner wall of the photosensitive resin 17 defines a second opening 18, which exposes the inward portion of the first main surface electrode 11, in the inward portion of the first main surface electrode 11. The second opening 18 is formed in a quadrangular shape along the peripheral edge of the first main surface electrode 11 in a plan view. The outer wall of the photosensitive resin 17 is formed at an interval inward from the peripheral edge of the first main surface 3, and defines the dicing street 16 that exposes the peripheral edge portion of the first main surface 3.

In this embodiment, the photosensitive resin 17 is formed on the second inorganic insulating film 14 such as to expose both an inner peripheral edge portion (inner wall) and an outer peripheral edge portion (outer wall) of the second inorganic insulating film 14. Therefore, the inner wall of the photosensitive resin 17 defines the second opening 18 that communicates with the first opening 15 of the second inorganic insulating film 14. Also, the outer wall of the photosensitive resin 17 defines the dicing street 16 together with the second inorganic insulating film 14. If the outer wall of the second inorganic insulating film 14 is continuous to the side surface 5 (first to fourth side surfaces 5A to 5D) of the chip 2, the outer wall of the photosensitive resin 17 defines the dicing street 16 that exposes the second inorganic insulating film 14.

The inner wall of the photosensitive resin 17 may be formed in a curved shape that bulges toward the inward portion side of the first main surface electrode 11. The outer wall of the photosensitive resin 17 may be formed in a curved shape that bulges toward the peripheral edge side of the chip 2. The photosensitive resin 17 may cover either one or both of the inner wall and the outer wall of the second inorganic insulating film 14. In other words, the photosensitive resin 17 may have ether one or both of a portion that directly covers a part of the first main surface electrode 11 and a portion that directly covers a peripheral edge portion (second semiconductor region 7) of the chip 2.

Preferably, the photosensitive resin 17 has a thickness exceeding the thickness of the first inorganic insulating film 9. Preferably, the thickness of the photosensitive resin 17 exceeds the thickness of the second inorganic insulating film 14. Preferably, the thickness of the photosensitive resin 17 exceeds the thickness of the first main surface electrode 11. The thickness of the photosensitive resin 17 may be not less than 3 μm and not more than 30 μm. Preferably, the thickness of the photosensitive resin 17 is equal to or less than 20 μm.

The photosensitive resin 17 may be a negative type or a positive type. The photosensitive resin 17 may include at least one among a polyimide film, a polyamide film, and a polybenzoxazole film. In this embodiment, the photosensitive resin 17 includes a polybenzoxazole film.

The wide bandgap semiconductor device 1A includes a thermosetting resin 19 that covers the first main surface 3. The thermosetting resin 19 may be referred to as a “sealing resin,” a “second organic film,” or a “second organic insulating film.” In this embodiment, the thermosetting resin 19 covers the photosensitive resin 17 such as to expose at least one part of the first main surface electrode 11, and covers the first main surface electrode 11 and the second inorganic insulating film 14 with the photosensitive resin 17 between the thermosetting resin 19 and the first main surface electrode 11 and between the thermosetting resin 19 and the second inorganic insulating film 14.

The thermosetting resin 19 extends as a band along the peripheral edge of the first main surface 3 in a plan view. In this embodiment, the thermosetting resin 19 is formed in an annular shape (in detail, quadrangular annular shape) surrounding the inward portion of the first main surface electrode 11 in a plan view, and covers the peripheral edge portion of the first main surface electrode 11 with the photosensitive resin 17 between the thermosetting resin 19 and the first main surface electrode 11 over the entire periphery. In this embodiment, the thermosetting resin 19 covers the lead-out portion 11b of the first main surface electrode 11 with the photosensitive resin 17 between the thermosetting resin 19 and the first main surface electrode 11, and exposes the main body portion 11a. If the photosensitive resin 17 covers the main body portion 11a, the thermosetting resin 19 may cover a part of the main body portion 11a with the photosensitive resin 17 between the thermosetting resin 19 and the main body portion 11a.

In this embodiment, the thermosetting resin 19 exposes the inner wall (second opening 18) of the photosensitive resin 17, and covers the outer wall of the photosensitive resin 17. The thermosetting resin 19 covers the dicing street 16 defined by the photosensitive resin 17 (second inorganic insulating film 14) in the peripheral edge portion of the chip 2. The thermosetting resin 19 directly covers the second semiconductor region 7 exposed from the first main surface 3 in the dicing street 16.

The thermosetting resin 19 has a resin main surface 20, a resin inner wall 21 on the inward portion side of the first main surface electrode 11, and a resin side surface 22 on the peripheral edge side of the first main surface 3. The resin main surface 20, the resin inner wall 21, and the resin side surface 22 may be referred to as an “organic main surface,” an “organic inner wall,” and an “organic side surface,” respectively. The resin main surface 20 extends along the first main surface 3. In detail, the resin main surface 20 extends in substantially parallel to the first main surface 3. Preferably, the resin main surface 20 is constituted of a ground surface having grinding marks.

The resin inner wall 21 defines a pad opening 23, which exposes the inward portion of the first main surface electrode 11, in the inward portion of the resin main surface 20. In this embodiment, the pad opening 23 communicates with the first opening 15 of the second inorganic insulating film 14 and with the second opening 18 of the photosensitive resin 17. The pad opening 23 is formed in a quadrangular shape along the peripheral edge of the chip 2 (first main surface electrode 11) in a plan view. Preferably, the resin inner wall 21 is constituted of a smooth surface having no grinding marks.

The resin inner wall 21 has an upper end portion (opening end) on the resin main surface 20 side and a lower end portion on the chip 2 (photosensitive resin 17) side. The lower end portion of the resin inner wall 21 is hollowed along an outside surface of the photosensitive resin 17, and forms a gap 24 with the photosensitive resin 17. In detail, the resin inner wall 21 has a first wall portion 25 on the opening end side and a second wall portion 26 on the lower end portion side. The first wall portion 25 extends in a thickness direction between the opening end and the lower end portion. Preferably, the first wall portion 25 occupies a range of 80% or more of the resin inner wall 21 in a cross-sectional view.

The second wall portion 26 extends in a direction intersecting the first wall portion 25 toward the outer wall of the photosensitive resin 17 between the outside surface of the photosensitive resin 17 and the first wall portion 25, and defines the gap 24 with the outside surface of the photosensitive resin 17. In detail, the second wall portion 26 is obliquely inclined from the first wall portion 25 toward the outside surface of the photosensitive resin 17, and defines the gap 24 having a tapered shape in which a width along the normal direction Z becomes gradually smaller in proportion to a distance receding from the first wall portion 25 (first main surface electrode 11). Preferably, the second wall portion 26 (gap 24) occupies a range less than 20% of the resin inner wall 21 in a cross-sectional view.

The resin side surface 22 includes first to fourth resin side surfaces 22A to 22D. The first resin side surface 22A is positioned on the first side surface 5A side, the second resin side surface 22B is positioned on the second side surface 5B side, the third resin side surface 22C is positioned on the third side surface 5C side, and the fourth resin side surface 22D is positioned on the fourth side surface 5D side. The first resin side surface 22A and the second resin side surface 22B extend in the first direction X along the first main surface 3, and face the second direction Y. The third resin side surface 22C and the fourth resin side surface 22D extend in the second direction Y, and face the first direction X.

The resin side surface 22 (first to fourth resin side surfaces 22A to 22D) extends toward the chip 2, and forms a resin outer wall. The resin side surface 22 is formed substantially at right angle with respect to the resin main surface 20. The angle made by the resin side surface 22 with the resin main surface 20 may be not less than 88° and not more than 92°. The resin side surface 22 is continuous to the side surface 5 of the chip 2 (first to fourth side surfaces 5A to 5D). Preferably, the resin side surface 22 is constituted of a ground surface having grinding marks. Preferably, the resin side surface 22 forms a single ground surface together with the side surface 5 of the chip 2.

Preferably, the thermosetting resin 19 has a thickness exceeding the thickness of the first inorganic insulating film 9. Preferably, the thickness of the thermosetting resin 19 exceeds the thickness of the second inorganic insulating film 14. Preferably, the thickness of the thermosetting resin 19 exceeds the thickness of the first main surface electrode 11. Particularly preferably, the thickness of the thermosetting resin 19 exceeds the thickness of the photosensitive resin 17. In this embodiment, the thickness of the thermosetting resin 19 exceeds the thickness of the chip 2. The thickness of the thermosetting resin 19 may be not less than 10 μm and not more than 300 μm. Preferably, the thickness of the thermosetting resin 19 is equal to or more than 30 μm. The thickness of the thermosetting resin 19 may be equal to or less than 200 μm.

The thermosetting resin 19 has a rigidity higher than that of the photosensitive resin 17. In other words, the thermosetting resin 19 has an elastic modulus larger than that of the photosensitive resin 17. The thermosetting resin 19 reinforces the chip 2 from above the first main surface 3. Referring to FIG. 4, the thermosetting resin 19 is composed of a matrix resin 27 and a plurality of fillers 28. The matrix resin 27 may include at least one among an epoxy resin, a phenol resin, and a thermosetting polyimide resin. In this embodiment, the matrix resin 27 includes an epoxy resin. The matrix resin 27 may be colored by a coloring material, such as carbon black.

The fillers 28 are respectively constituted of spherical substances composed of ceramics, oxides, insulators, etc. In other words, the fillers 28 are not formed in a fibrous manner. In this embodiment, the fillers 28 are respectively constituted of silicon oxide particles (silica particles). The thermosetting resin 19 includes a plurality of fillers 28 differ from each other in particle size.

In detail, the fillers 28 include a plurality of small size fillers 28a (first fillers), a plurality of intermediate size fillers 28b (second fillers), and a plurality of large size fillers 28c (third fillers). The small size filler 28a has a thickness less than the thickness of the first main surface electrode 11. The intermediate size filler 28b has a thickness that exceeds the thickness of the first main surface electrode 11 and that is equal to or less than the thickness of the photosensitive resin 17. The large size filler 28c has a thickness exceeding the thickness of the photosensitive resin 17.

The small size fillers 28a, the intermediate size fillers 28b, and the large size fillers 28c are filled together with the matrix resin 27 in a region closer to the resin main surface 20 than to the photosensitive resin 17. A filler attack against a structure arranged on the chip 2 side, which is caused by the intermediate diameter and large size fillers 28b and 28c, is relaxed by the photosensitive resin 17.

The small size fillers 28a and the intermediate size fillers 28b are filled together with the matrix resin 27 in a region lower than the photosensitive resin 17. Particularly, the small diameter filler 28a is filled together with the matrix resin 27 in a gap (in this embodiment, a gap between the second inorganic insulating film 14 and the photosensitive resin 17) that is formed because of the photosensitive resin 17. An adhesive force of the matrix resin 27 to a structure arranged on the chip 2 side is raised also by the fillers 28 that differ from each other in particle size.

The fillers 28 include a plurality of filler fragments 29 having broken particle shapes in a surface layer portion of the thermosetting resin 19. The filler fragments 29 includes a plurality of first filler fragments 29a (main surface side filler fragments) formed at a surface layer portion of the resin main surface 20 and a plurality of second filler fragments 29b (side surface side filler fragments) formed at a surface layer portion of the resin side surface 22.

The first filler fragment 29a and the second filler fragment 29b are each formed by any one of a part of the small size filler 28a, a part of the intermediate size filler 28b, and a part of the large size filler 28c. Each of the filler fragments 29 forms a part of the grinding marks in an outside surface of the thermosetting resin 19.

The thermosetting resin 19 has almost no filler fragment 29 in a surface layer portion of the resin inner wall 21 (first and second wall portions 25 and 26). In other words, the resin inner wall 21 (pad opening 23) is formed by the matrix resin 27 and normal fillers 28. In this case, the percentage of filler fragments 29 among the fillers 28 forming the resin inner wall 21 is less than the percentage of normal fillers 28 forming the resin inner wall 21.

The wide bandgap semiconductor device 1A includes a pad electrode 30 arranged on an exposed portion of the first main surface electrode 11. The pad electrode 30 is an external terminal electrically connected to a conductive connecting member (for example, a lead wire, a conductive plate, and the like). The pad electrode 30 is arranged on the first main surface electrode 11 at an interval inward from the peripheral edge of the first main surface electrode 11. In this embodiment, the pad electrode 30 is arranged in the pad opening 23, and covers the inward portion of the first main surface electrode 11. In other words, the pad electrode 30 is in contact with the matrix resin 27 and with the fillers 28 in the pad opening 23.

The pad electrode 30 is not arranged outside the pad opening 23. The pad electrode 30 has a planar shape (in this embodiment, quadrangular shape) that matches the pad opening 23 in a plan view. The pad electrode 30 has a plane area less than the plane area of the first main surface electrode 11. In this embodiment, the pad electrode 30 enters the second opening 18 and the first opening 15 from the pad opening 23, and is in contact with the first main surface electrode 11, with the second inorganic insulating film 14, with the photosensitive resin 17, and with the thermosetting resin 19.

Preferably, the pad electrode 30 has a thickness exceeding the thickness of the first inorganic insulating film 9. Preferably, the thickness of the pad electrode 30 exceeds the thickness of the second inorganic insulating film 14. Preferably, the thickness of the pad electrode 30 exceeds the thickness of the first main surface electrode 11. Particularly preferably, the thickness of the pad electrode 30 exceeds the thickness of the photosensitive resin 17. In this embodiment, the thickness of the pad electrode 30 exceeds the thickness of the chip 2.

The thickness of the pad electrode 30 may be not less than 10 μm and not more than 300 μm. Preferably, the thickness of the pad electrode 30 is equal to or more than 30 μm. The thickness of the pad electrode 30 may be equal to or less than 200 μm. The pad electrode 30, which is comparatively thick (for example, is thicker than the first main surface electrode 11), is used also as a heat sink electrode that dissipates heat generated on the chip 2 side to the outside.

The pad electrode 30 has an electrode surface 30a exposed from the thermosetting resin 19 (pad opening 23). The electrode surface 30a extends along the first main surface 3. In detail, the electrode surface 30a extends in substantially parallel to the first main surface 3. The electrode surface 30a is continuous to the resin main surface 20 of the thermosetting resin 19. The electrode surface 30a is constituted of a ground surface having grinding marks. The electrode surface 30a forms a single ground surface together with the resin main surface 20.

The pad electrode 30 has an overhanging portion 30b that rides on the outside surface of the photosensitive resin 17 in the gap 24 of the thermosetting resin 19. The overhanging portion 30b is in contact with the photosensitive resin 17 and with the thermosetting resin 19 in the gap 24, and has a sectional shape that matches the gap 24. In other words, the overhanging portion 30b is inclined obliquely downward from the first wall portion 25 side toward the outside surface of the photosensitive resin 17, and is formed in a tapered shape in which a thickness gradually becomes smaller in proportion to a distance receding from the first wall portion 25.

The length along the first main surface 3 of the overhanging portion 30b may exceed the thickness of the photosensitive resin 17. As a matter of course, the length of the overhanging portion 30b may be equal to or less than the thickness of the photosensitive resin 17. The overhanging portion 30b suppresses the fall-off of the pad electrode 30 from the thermosetting resin 19. The overhanging portion 30b may be referred to as a “fall-off stopper portion.”

Referring to FIG. 4, the pad electrode 30 includes a first pad electrode film 31 and a second pad electrode film 32 that are laminated in that order from the first main surface electrode 11 side. The first pad electrode film 31 covers the first main surface electrode 11. In this embodiment, the first pad electrode film 31 is lead out as a film from above the first main surface electrode 11 onto the second inorganic insulating film 14 and onto the photosensitive resin 17.

The first pad electrode film 31 has a portion whose thickness is less than the thickness of the first main surface electrode 11 and that is positioned in the first opening 15 and in the second opening 18. The first pad electrode film 31 has a portion whose thickness is less than the width of the gap 24 and that covers the photosensitive resin 17 in the gap 24 with respect to the thickness direction (normal direction Z). In this embodiment, the first pad electrode film 31 partially covers the second wall portion 26 of the pad opening 23 in the gap 24, and exposes the first wall portion 25 of the pad opening 23.

The second pad electrode film 32 covers the first pad electrode film 31, and forms the main body of the pad electrode 30. The second pad electrode film 32 has a thickness exceeding the thickness of the photosensitive resin 17 (in this embodiment, the thickness of the chip 2), and has a portion positioned in the first opening 15, in the second opening 18, and in the pad opening 23.

The second pad electrode film 32 has a thickness exceeding the width of the gap 24, and has a portion in contact with the first pad electrode film 31 and with the thermosetting resin 19 in the gap 24 with respect to the thickness direction (normal direction Z). In other words, the overhanging portion 30b of the pad electrode 30 film includes the first pad electrode film 31 and the second pad electrode film 32. The electrode surface 30a of the pad electrode 30 is formed by the second pad electrode film 32.

In this embodiment, the first pad electrode film 31 is constituted of a seed film formed by a sputtering method. The first pad electrode film 31 may include a Ti-based metal film. The first pad electrode film 31 may have a single layer structure constituted of a Ti film or a TiN film. The first pad electrode film 31 may have a laminated structure including a Ti film and a TiN film that are laminated in arbitrary order. In this embodiment, the second pad electrode film 32 is constituted of a plating film formed by an electrolytic plating method or an electroless plating method. The second pad electrode film 32 may include a Cu-based metal plating film. In this embodiment, the second pad electrode film 32 has a single layer structure constituted of a pure Cu plating film (a Cu film whose purity is 99% or more).

The pad electrode 30 may have at least one minute void space 33 at a connection portion with the first main surface electrode 11. In FIG. 4, an example is shown in which the void space 33 is formed between the first pad electrode film 31 and the first main surface electrode 11. As a matter of course, the void space 33 may be formed between the first pad electrode film 31 and the second pad electrode film 32. The void space 33 has a size smaller than the thickness of the first main surface electrode 11. The size of the void space 33 may be equal to or less than 1 μm with respect to the thickness direction of the pad electrode 30. Preferably, the size of the void space 33 is equal to or less than 0.5 μm.

The wide bandgap semiconductor device 1A includes a second main surface electrode 34 that covers the second main surface 4. The second main surface electrode 34 is electrically connected to the second main surface 4. In detail, the second main surface electrode 34 forms an ohmic contact with the first semiconductor region 6 exposed from the second main surface 4. The second main surface electrode 34 covers the whole area of the second main surface 4 such as to be continuous to the peripheral edge (first to fourth side surfaces 5A to 5D) of the chip 2. Preferably, the outer wall of the second main surface electrode 34 is constituted of a ground surface having grinding marks. Preferably, the outer wall of the second main surface electrode 34 forms a single ground surface together with the side surface 5 of the chip 2.

As described above, the wide bandgap semiconductor device 1A includes the chip 2, the first main surface electrode 11, and the thermosetting resin 19. The chip 2 includes a wide bandgap semiconductor, and has the first main surface 3. The first main surface electrode 11 covers the first main surface 3. The thermosetting resin 19 is composed of the matrix resin 27 and the fillers 28, and covers the first main surface 3 such as to expose at least one part of the first main surface electrode 11.

With this structure, it is possible to reinforce and protect the chip 2 by means of the thermosetting resin 19 while securing a contact portion with the first main surface electrode 11. Therefore, it is possible to provide the wide bandgap semiconductor device 1A capable of improving reliability.

Preferably, the thermosetting resin 19 covers the peripheral edge portion of the first main surface electrode 11. The wide bandgap semiconductor device 1A is mounted on a vehicle or the like in which a motor of a hybrid automobile, of an electric automobile, of a fuel cell vehicle, etc., is used as a driving source in consideration of the properties of the wide bandgap semiconductor. Therefore, the wide bandgap semiconductor device 1A is required to have durability that meets severe use environment conditions. The durability of the wide bandgap semiconductor device 1A is evaluated by, for example, a high temperature/high humidity bias test. In the high temperature/high humidity bias test, the electrical operation of the wide bandgap semiconductor device 1A is evaluated in a state of being exposed in a high temperature/high humidity environment.

Under a high temperature environment, there is a possibility that the first main surface electrode 11 peels off by means of stress caused by the thermal expansion of the first main surface electrode 11. Under a high humidity environment, there is a possibility that the electrical properties of the first main surface electrode 11 and the like varies because of water (moisture) that has entered a peeled portion of the first main surface electrode 11. Therefore, with the thermosetting resin 19 covering the peripheral edge portion of the first main surface electrode 11, it is possible to reduce peel-off starting points of the first main surface electrode 11 and, at the same time, to suppress entry of water from the outside. Therefore, it is possible to provide the wide bandgap semiconductor device 1A capable of improving reliability.

Preferably, the wide bandgap semiconductor device 1A further include the photosensitive resin 17 covering the peripheral edge portion of the first main surface electrode 11. In this case, preferably, the thermosetting resin 19 covers the photosensitive resin 17. With this structure, it is possible to reduce the peel-off starting points of the first main surface electrode 11 by means of both the photosensitive resin 17 and the thermosetting resin 19.

In this structure, the fillers 28 may include the large size fillers 28c that are thicker than the photosensitive resin 17. With this structure, it is possible to improve the flowability of the matrix resin 27 by use of the large size fillers 28c, and, at the same time, to relax a shock caused by the large size filler 28c by means of the photosensitive resin 17. Therefore, it is possible to form the thermosetting resin 19 that appropriately protects the photosensitive resin 17, etc.

Preferably, the wide bandgap semiconductor device 1A includes the pad electrode 30 electrically connected to the first main surface electrode 11 in the pad opening 23 of the thermosetting resin 19. With this structure, in a structure in which a level difference is formed between the first main surface electrode 11 and the thermosetting resin 19, it is possible to appropriately transmit an electric signal between the first main surface electrode 11 and a conductive connecting member (for example, a lead wire or a conductive plate, etc.) by means of the pad electrode 30.

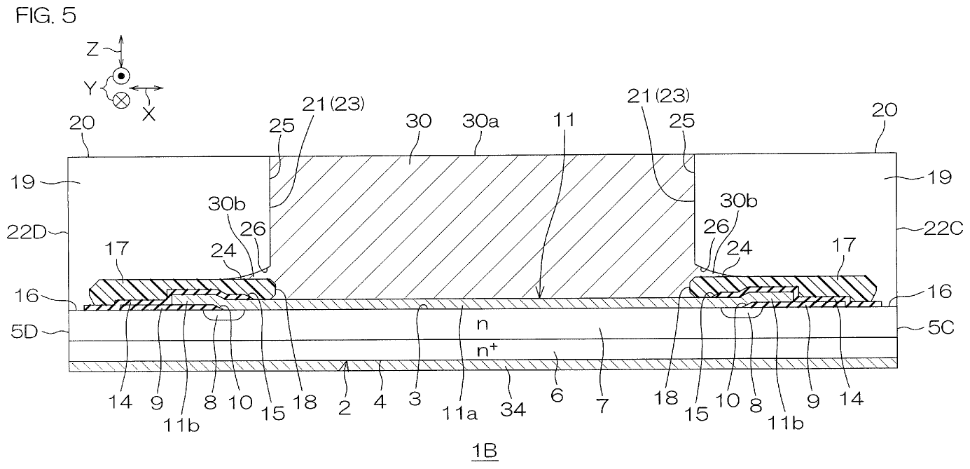

FIG. 5 corresponds to FIG. 3, and is a cross-sectional view showing a wide bandgap semiconductor device 1B according to a second embodiment. In the first embodiment, an example was described in which the photosensitive resin 17 exposes the inner peripheral edge portion (inner wall) of the second inorganic insulating film 14. On the other hand, the wide bandgap semiconductor device 1B includes the photosensitive resin 17 covering the inner peripheral edge portion (inner wall) of the second inorganic insulating film 14.

In other words, the photosensitive resin 17 includes a portion that directly covers the first main surface electrode 11. The resin inner wall 21 (pad opening 23) of the thermosetting resin 19 exposes the photosensitive resin 17 and the inward portion of the first main surface electrode 11, and does not expose the second inorganic insulating film 14. The pad electrode 30 is in contact with the first main surface electrode 11, with the photosensitive resin 17, and with the thermosetting resin 19, and is not in contact with the second inorganic insulating film 14 in the pad opening 23.

As described above, the same effect as the effect described with respect to the wide bandgap semiconductor device 1A is likewise fulfilled by the wide bandgap semiconductor device 1B.

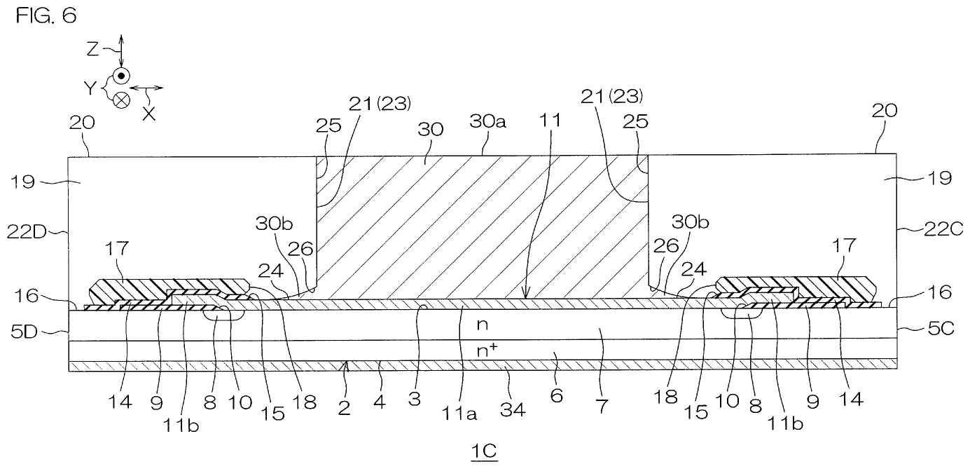

FIG. 6 corresponds to FIG. 3, and is a cross-sectional view showing a wide bandgap semiconductor device 1C according to a third embodiment. In the first embodiment, an example was described in which the thermosetting resin 19 exposes the inner peripheral edge portion (inner wall) of the second inorganic insulating film 14 and the inner peripheral edge portion (inner wall) of the photosensitive resin 17. On the other hand, the wide bandgap semiconductor device 1C includes the thermosetting resin 19 that covers the inner peripheral edge portion (inner wall) of the second inorganic insulating film 14 and the inner peripheral edge portion (inner wall) of the photosensitive resin 17.

In other words, the thermosetting resin 19 includes a portion that directly covers the first main surface electrode 11. The resin inner wall 21 (pad opening 23) of the thermosetting resin 19 exposes only the first main surface electrode 11, and exposes neither the second inorganic insulating film 14 nor the photosensitive resin 17. In this embodiment, the lower end portion of the resin inner wall 21 forms the gap 24 with the first main surface electrode 11. The pad electrode 30 is in contact with the first main surface electrode 11 and with the thermosetting resin 19, and is in contact with neither the second inorganic insulating film 14 nor the photosensitive resin 17 in the pad opening 23.

As described above, the same effect as the effect described with respect to the wide bandgap semiconductor device 1A is likewise fulfilled by the wide bandgap semiconductor device 1C. As a matter of course, the form of the thermosetting resin 19 according to the third embodiment may be applied to the second embodiment.

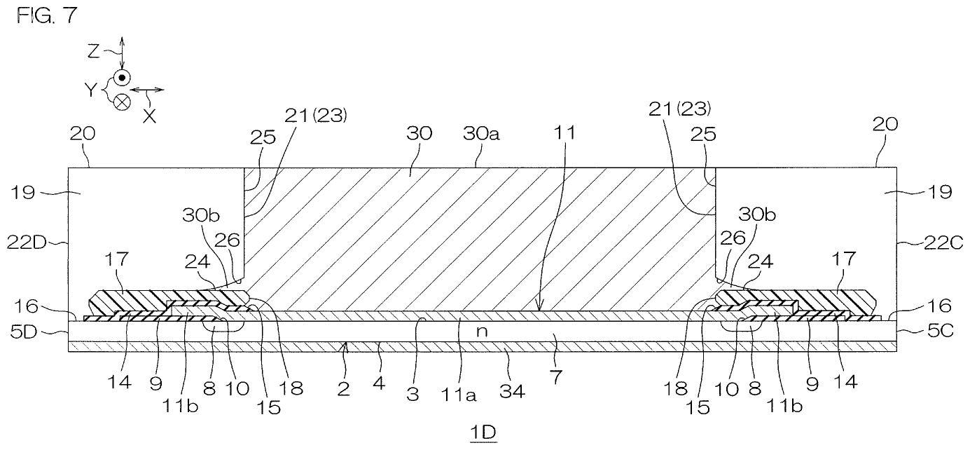

FIG. 7 corresponds to FIG. 3, and is a cross-sectional view showing a wide bandgap semiconductor device 1D according to a fourth embodiment. In the first embodiment, an example was described in which the chip 2 has a laminated structure including the first semiconductor region 6 (wide bandgap semiconductor substrate) and the second semiconductor region 7 (wide bandgap semiconductor epitaxial layer) that are formed in that order from the second main surface 4 side.

On the other hand, the wide bandgap semiconductor device 1D does not have the first semiconductor region 6 (wide bandgap semiconductor substrate), and includes the chip 2 having a single layer structure constituted of the second semiconductor region 7 (wide bandgap semiconductor epitaxial layer).

As described above, the same effect as the effect described with respect to the wide bandgap semiconductor device 1A is likewise fulfilled by the wide bandgap semiconductor device 1D. Also, with the wide bandgap semiconductor device 1D, it is possible to reduce the resistance value of the first semiconductor region 6, and therefore it is possible to reduce the resistance value of the entirety of the chip 2. Also, the chip 2 is supported by the thermosetting resin 19, and therefore it is possible to supplement the strength of the chip 2, which has been thinned, by means of the thermosetting resin 19. Therefore, it is possible to provide the wide bandgap semiconductor device 1D capable of improving electrical properties while raising reliability. As a matter of course, the form of the chip 2 according to the fourth embodiment may be applied to the second and third embodiments.

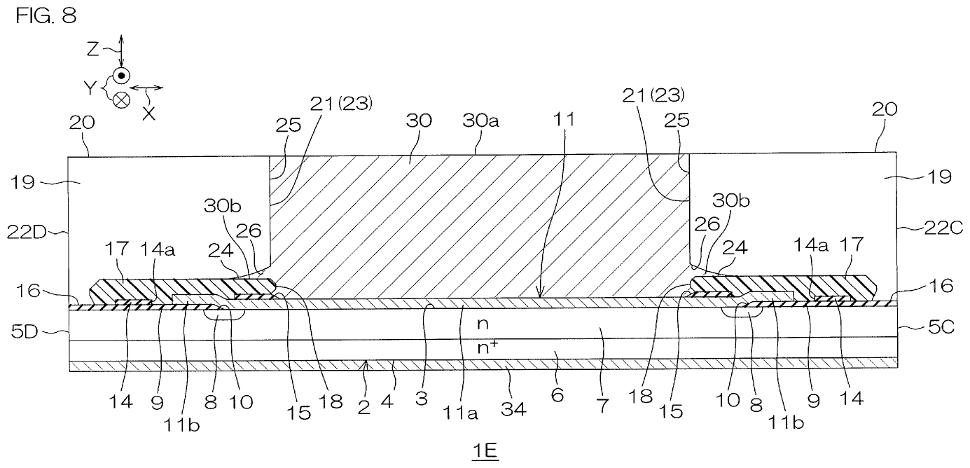

FIG. 8 corresponds to FIG. 3, and is a cross-sectional view showing a wide bandgap semiconductor device 1E according to a fifth embodiment. In the first embodiment, an example was described in which the second inorganic insulating film 14 covers the peripheral edge portion of the first main surface electrode 11. On the other hand, the wide bandgap semiconductor device 1E includes the second inorganic insulating film 14 that has a removed portion 14a exposing an electrode sidewall of the first main surface electrode 11 and that partially covers the first main surface electrode 11. A structure of the wide bandgap semiconductor device 1E shall be hereinafter described in detail.

In this embodiment, the first inorganic insulating film 9 covers the whole area of a region between the peripheral edge of the first main surface 3 and the guard region 8. The first inorganic insulating film 9 has an outer wall continuous to the side surface 5 (first to fourth side surfaces 5A to 5D) of the chip 2. The outer wall of the first inorganic insulating film 9 is constituted of a ground surface having grinding marks. The outer wall of the first inorganic insulating film 9 forms a single ground surface together with the side surface 5 (first to fourth side surfaces 5A to 5D) of the chip 2. As a matter of course, the first inorganic insulating film 9 may be formed in the same manner as in the first embodiment.

The second inorganic insulating film 14 covers the first main surface electrode 11 and the first inorganic insulating film 9, and has an inner wall on the inward portion side of the first main surface electrode 11 and an outer wall on the peripheral edge side of the first main surface 3 in the same way as in the first embodiment. The inner wall of the second inorganic insulating film 14 defines the first opening 15 that exposes an inward portion (main body portion 11a) of the first main surface electrode 11. In this embodiment, the outer wall of the second inorganic insulating film 14 is formed at an interval inward from the peripheral edge of the first main surface 3, and defines the dicing street 16 that exposes the first inorganic insulating film 9.

In this embodiment, the second inorganic insulating film 14 has at least one removed portion 14a that exposes the electrode sidewall of the first main surface electrode 11 between the first main surface electrode 11 and the first inorganic insulating film 9. In detail, the removed portion 14a is formed at an interval from the inner wall and from the outer wall, and exposes the peripheral edge portion of the first main surface electrode 11 and a part of the first inorganic insulating film 9.

The second inorganic insulating film 14 may cover a part of the main body portion 11a and a part of the lead-out portion 11b, or may cover a part of the main body portion 11a at an interval from the lead-out portion 11b. In other words, the removed portion 14a may expose a part of or the entirety of the lead-out portion 11b, or may expose the entirety of the lead-out portion 11b and a part of the main body portion 11a.

If the second inorganic insulating film 14 has a single removed portion 14a, the single removed portion 14a may be formed as a band extending along the peripheral edge portion of the first main surface electrode 11 in a plan view, and may partially expose the peripheral edge portion of the first main surface electrode 11. Also, the single removed portion 14a may be formed in an annular shape extending along the peripheral edge portion of the first main surface electrode 11, and may expose the peripheral edge portion of the first main surface electrode 11 over the entire periphery.

If the second inorganic insulating film 14 has a plurality of removed portions 14a, the removed portions 14a may be arranged at intervals from each other along the peripheral edge portion of the first main surface electrode 11. In this case, the removed portions 14a may be arranged in a dot manner in a plan view, or may be each formed as a band extending along the peripheral edge portion of the first main surface electrode 11.

Also, the removed portions 14a may be arranged at intervals from the peripheral edge portion toward the inward portion of the first main surface electrode 11. In this case, the removed portions 14a may be arranged in a dot manner in a plan view, or may be each formed as a band or in an annular shape extending along the peripheral edge portion of the first main surface electrode 11. In this case, it suffices that at least one removed portion 14a exposes the electrode sidewall (peripheral edge portion) of the first main surface electrode 11.

In this embodiment, the photosensitive resin 17 enters the removed portion 14a from above the second inorganic insulating film 14. The photosensitive resin 17 covers the electrode sidewall of the first main surface electrode 11 in the removed portion 14a. In detail, the photosensitive resin 17 directly covers the peripheral edge portion of the first main surface electrode 11 and a part of the first inorganic insulating film 9 in the removed portion 14a. In other words, the photosensitive resin 17 has a resin anchor portion positioned in the removed portion 14a.

In this embodiment, the thermosetting resin 19 includes a portion covering the removed portion 14a of the second inorganic insulating film 14 with the photosensitive resin 17 between the thermosetting resin 19 and the removed portion 14a. In other words, the thermosetting resin 19 includes a portion covering the first inorganic insulating film 9 and the peripheral edge portion of the first main surface electrode 11 with only the photosensitive resin 17, without the second inorganic insulating film 14, between the thermosetting resin 19 and each of the first inorganic insulating film 9 and the first main surface electrode 11. Preferably, the thermosetting resin 19 covers the whole area of the removed portion 14a in a plan view and in a cross-sectional view. In this embodiment, the thermosetting resin 19 includes a portion that directly covers the first inorganic insulating film 9 exposed from the first main surface 3 in the dicing street 16.

As described above, the same effect as the effect described with respect to the wide bandgap semiconductor device 1A is likewise fulfilled by the wide bandgap semiconductor device 1E. Also, the wide bandgap semiconductor device 1E includes the second inorganic insulating film 14 having the removed portion 14a that exposes the electrode sidewall of the first main surface electrode 11. With this structure, it is possible to reduce the peel-off starting points of the second inorganic insulating film 14 caused by the thermal expansion of the first main surface electrode 11. Therefore, it is possible to provide the wide bandgap semiconductor device 1E capable of improving reliability.

In the thus formed structure, the wide bandgap semiconductor device 1E includes the photosensitive resin 17 covering the electrode sidewall of the first main surface electrode 11 in the removed portion 14a. With this structure, it is possible to reduce the peel-off starting points of the first main surface electrode 11 in a structure in which the second inorganic insulating film 14 has the removed portion 14a. Therefore, it is possible to provide the wide bandgap semiconductor device 1E capable of improving reliability.

Also, in the thus formed structure, the wide bandgap semiconductor device 1E has the thermosetting resin 19 including a part covering the removed portion 14a of the second inorganic insulating film 14 with the photosensitive resin 17 between the thermosetting resin 19 and the removed portion 14a. With this structure, it is possible to reduce the peel-off starting points of the first main surface electrode 11 by means of the photosensitive resin 17 and the thermosetting resin 19 in a structure in which the second inorganic insulating film 14 has the removed portion 14a. As a matter of course, the form of the first inorganic insulating film 9, the form of the first main surface electrode 11, the form of the second inorganic insulating film 14, the form of the photosensitive resin 17, and the form of the thermosetting resin 19 that are according to the fifth embodiment may be applied to the second to fourth embodiments.

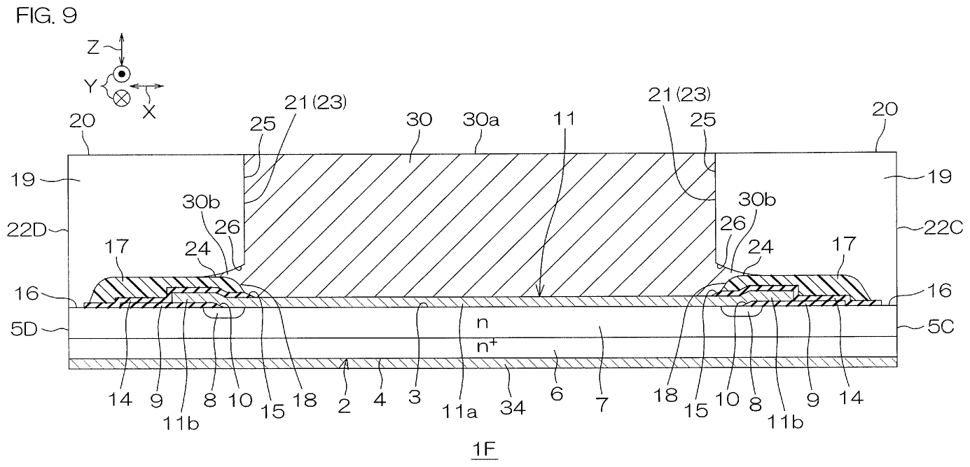

FIG. 9 corresponds to FIG. 3, and is a cross-sectional view showing a wide bandgap semiconductor device 1F according to a sixth embodiment. In the first embodiment, an example was described in which the photosensitive resin 17 has the curved inner wall that bulges toward the inward portion side of the first main surface electrode 11 and the curved outer wall that bulges toward the peripheral edge side of the chip 2. On the other hand, the wide bandgap semiconductor device 1F includes the photosensitive resin 17 having an inner wall that is inclined obliquely downward toward the inward portion side of the first main surface electrode 11 and an outer wall that is inclined obliquely downward toward the peripheral edge side of the chip 2. In other words, the photosensitive resin 17 is formed in a trapezoidal shape (tapered shape) in a cross-sectional view.

As described above, the same effect as the effect described with respect to the wide bandgap semiconductor device 1A is likewise fulfilled by the wide bandgap semiconductor device 1F. Also, with the wide bandgap semiconductor device 1F, it is possible to improve the flowability of the thermosetting resin 19 (matrix resin 27 and fillers 28) with respect to the photosensitive resin 17. Hence, it is possible to suppress the formation of a gap between the thermosetting resin 19 and the photosensitive resin 17. As a matter of course, the form of the photosensitive resin 17 according to the sixth embodiment may be applied to the second to fifth embodiments.

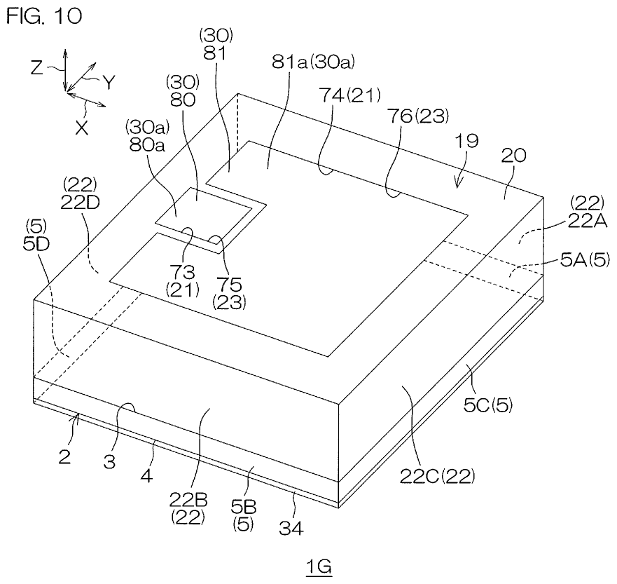

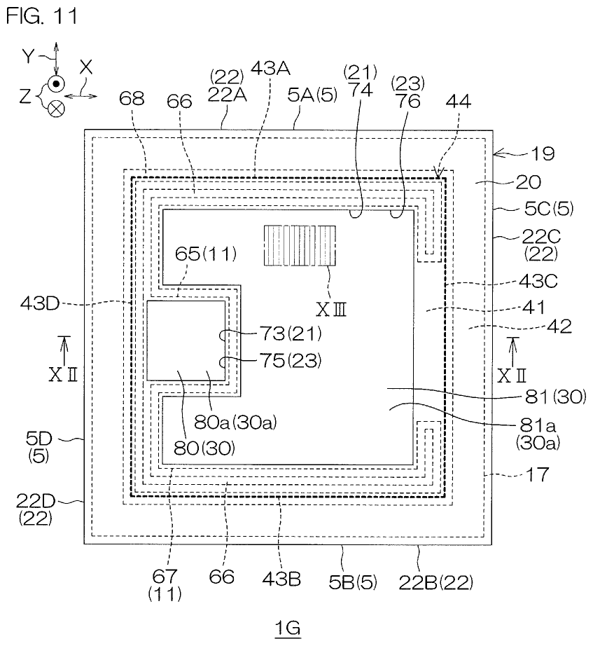

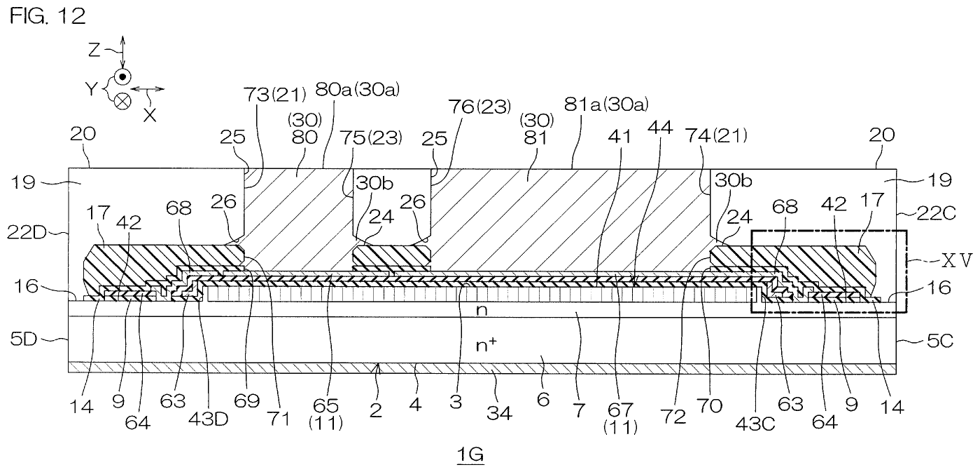

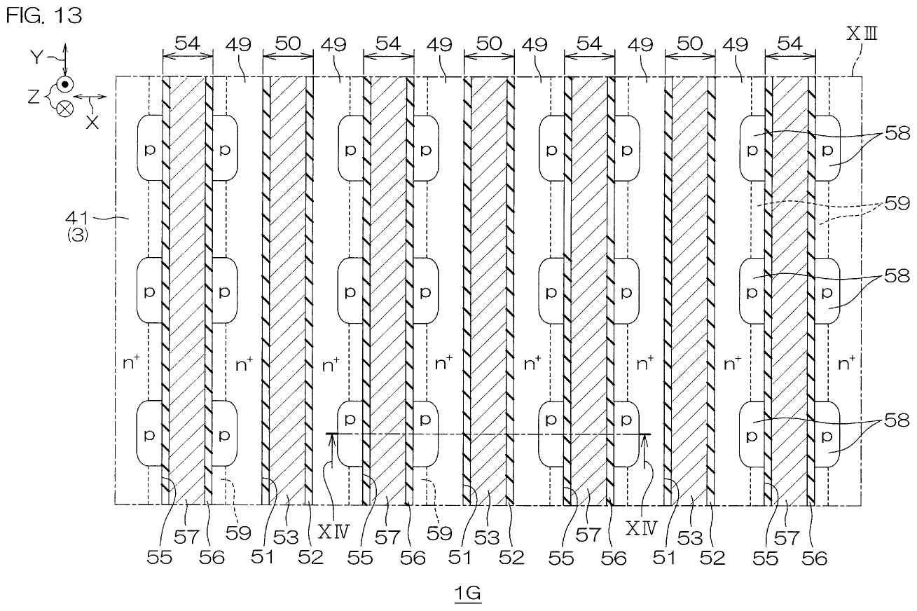

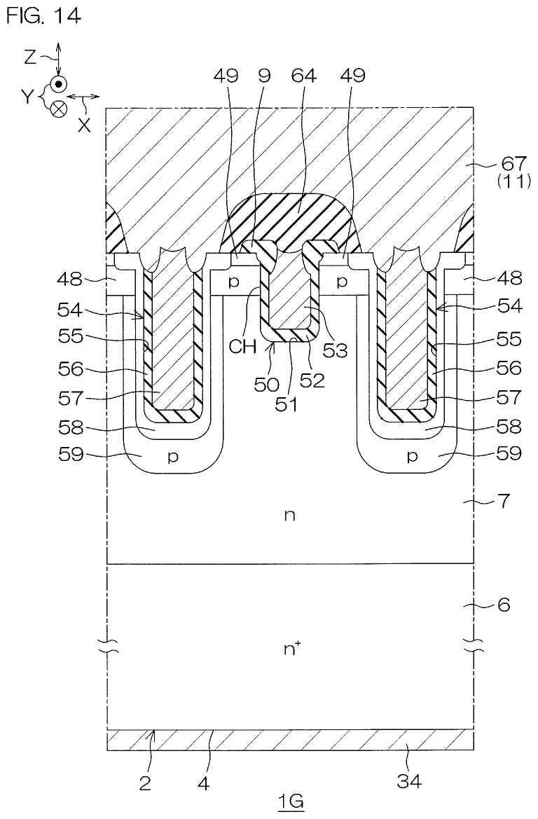

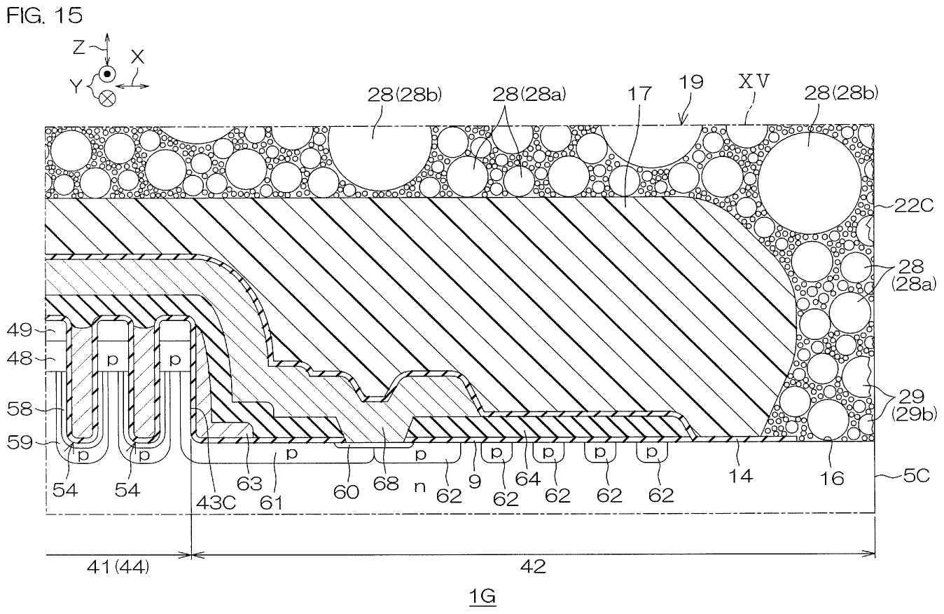

FIG. 10 is a perspective view showing a wide bandgap semiconductor device 1G according to a seventh embodiment. FIG. 11 is a plan view of the wide bandgap semiconductor device 1G shown in FIG. 10. FIG. 12 is a cross-sectional view taken along line XII-XII shown in FIG. 11. FIG. 13 is a plan view in which region XIII shown in FIG. 11 is shown together with an internal structure. FIG. 14 is a cross-sectional view taken along line XIV-XIV shown in FIG. 13. FIG. 15 is an enlarged view of region XV shown in FIG. 12.

Referring to FIG. 10 to FIG. 15, the wide bandgap semiconductor device 1G is a semiconductor device including a MISFET (Metal Insulator Semiconductor Field Effect Transistor) that is an example of a functional device. The wide bandgap semiconductor device 1G includes the chip 2 mentioned above, the first semiconductor region 6 mentioned above, and the second semiconductor region 7 mentioned above. In this embodiment, the wide bandgap semiconductor device 1G includes an active surface 41 formed at the first main surface 3 of the chip 2, an outer surface 42, and first to fourth connecting surfaces 43A to 43D.

The active surface 41, the outer surface 42, and the first to fourth connecting surfaces 43A to 43D define an active mesa 44 in the first main surface 3. The active surface 41 may be referred to as the “first surface,” the outer surface 42 may be referred to as the “second surface,” and the active mesa 44 may be referred to as the “mesa.” The active surface 41, the outer surface 42, and the first to fourth connecting surfaces 43A to 43D (i.e., active mesa 44) may be respectively regarded as components of the first main surface 3.

The active surface 41 is formed at an interval inward from the peripheral edge of the first main surface 3 (first to fourth side surfaces 5A to 5D). The active surface 41 has a flat surface extending in the first direction X and in the second direction Y. In this embodiment, the active surface 41 is formed in a quadrangular shape having four sides parallel to the first to fourth side surfaces 5A to 5D in a plan view.

The outer surface 42 is positioned outside the active surface 41, and is hollowed in the thickness direction (second main surface 4 side) of the chip 2 from the active surface 41. In detail, the outer surface 42 is hollowed with a depth less than the thickness of the second semiconductor region 7 such as to expose the second semiconductor region 7. The outer surface 42 is formed as a band extending along the active surface 41 in a plan view. In this embodiment, the outer surface 42 is formed in an annular shape (in detail, quadrangular annular shape) surrounding the active surface 41 in a plan view. The outer surface 42 has a flat surface extending in the first direction X and in the second direction Y, and is formed in substantially parallel to the active surface 41. The outer surface 42 is continuous to the first to fourth side surfaces 5A to 5D.

The first to fourth connecting surfaces 43A to 43D extend in the normal direction Z, and connect the active surface 41 and the outer surface 42 together. The first connecting surface 43A is positioned on the first side surface 5A side, the second connecting surface 43B is positioned on the second side surface 5B side, the third connecting surface 43C is positioned on the third side surface 5C side, and the fourth connecting surface 43D is positioned on the fourth side surface 5D side. The first connecting surface 43A and the second connecting surface 43B extend in the first direction X, and face the second direction Y. The third connecting surface 43C and the fourth connecting surface 43D extend in the second direction Y, and face the first direction X.

The first to fourth connecting surfaces 43A to 43D may substantially perpendicularly extend between the active surface 41 and the outer surface 42 such that a quadrangular-prism-shaped active mesa 44 is divisionally formed. The first to fourth connecting surfaces 43A to 43D may be inclined obliquely downward from the active surface 41 toward the outer surface 42 such that a quadrangular-frustum-shaped active mesa 44 is divisionally formed. Thus, the wide bandgap semiconductor device 1G includes the active mesa 44 formed in the second semiconductor region 7 in the first main surface 3. The active mesa 44 is formed only in the second semiconductor region 7, and is not formed in the first semiconductor region 6.

Referring to FIG. 13 and FIG. 14, the wide bandgap semiconductor device 1G includes a MISFET formed at the active surface 41. In this embodiment, the MISFET is a trench-gate type. A structure of the MISFET shall be hereinafter described in detail. The wide bandgap semiconductor device 1G includes a p-type body region 48 formed at a surface layer portion of the active surface 41. The body region 48 may be formed in the whole area of the surface layer portion of the active surface 41.

The wide bandgap semiconductor device 1G includes an n-type source region 49 formed at a surface layer portion of the body region 48. The source region 49 may be formed in the whole area of the surface layer portion of the body region 48. The source region 49 has an n-type impurity concentration exceeding an n-type impurity concentration of the second semiconductor region 7. The source region 49 forms a channel CH between the second semiconductor region 7 and the MISFET in the body region 48.

The wide bandgap semiconductor device 1G includes a plurality of trench gate structures 50 formed at the active surface 41. The trench gate structures 50 control the inversion and non-inversion of the channel CH. The trench gate structures 50 pass through the body region 48 and through the source region 49 to reach the second semiconductor region 7. The trench gate structures 50 are formed at an interval from a bottom portion of the second semiconductor region 7 toward the active surface 41 side. The trench gate structures 50 are formed at an interval from each other in the first direction X in a plan view, and are each formed as a band extending in the second direction Y.

Each of the trench gate structures 50 includes a gate trench 51, a gate insulating film 52, and a gate electrode 53. The gate trench 51 is formed at the active surface 41. The gate insulating film 52 covers an inner wall of the gate trench 51. The gate electrode 53 is buried in the gate trench 51 with the gate insulating film 52 between the gate electrode 53 and the gate trench 51. The gate electrode 53 faces the second semiconductor region 7, the body region 48, and the source region 49 with the gate insulating film 52 between the gate electrode 53 and each of the second semiconductor region 7, the body region 48, and the source region 49. A gate potential is to be applied to the gate electrode 53.

The wide bandgap semiconductor device 1G includes a plurality of trench source structures 54 formed at the active surface 41. The trench source structures 54 are each formed in a region between two adjacent trench gate structures 50 in the active surface 41. The trench source structures 54 are each formed as a band extending in the second direction Y in a plan view. The trench source structures 54 pass through the body region 48 and through the source region 49 to reach the second semiconductor region 7.

The trench source structures 54 are formed at an interval from the bottom portion of the second semiconductor region 7 toward the active surface 41 side. The trench source structures 54 each have a depth exceeding the depth of the trench gate structure 50. In this embodiment, the bottom wall of the trench source structures 54 is positioned such as to be substantially flush with the outer surface 42. As a matter of course, each of the trench source structures 54 may have a depth substantially equal to the depth of the trench gate structure 50.

Each of the trench source structures 54 includes a source trench 55, a source insulating film 56, and a source electrode 57. The source trench 55 is formed at the active surface 41. The source insulating film 56 covers an inner wall of the source trench 55. The source electrode 57 is buried in the source trench 55 with the source insulating film 56 between the source electrode 57 and the source trench 55. A source potential is to be applied to the source electrode 57.

The wide bandgap semiconductor device 1G includes a plurality of p-type contact regions 58 that are formed in regions along the trench source structures 54, respectively, in the second semiconductor region 7. A p-type impurity concentration of the contact regions 58 exceeds a p-type impurity concentration of the body region 48. The contact regions 58 each cover the trench source structure 54 that corresponds in one-to-many correspondence at an interval therefrom in the second direction Y. Each of the contact regions 58 covers a sidewall and a bottom wall of each of the trench source structures 54, and is electrically connected to the body region 48.

The wide bandgap semiconductor device 1G includes a plurality of p-type well regions 59 formed in regions along the trench source structures 54, respectively, in the surface layer portion of the active surface 41. Preferably, a p-type impurity concentration of the well regions 59 exceeds the p-type impurity concentration of the body region 48, and is less than the p-type impurity concentration of the contact region 58.

The well regions 59 each cover the trench source structure 54 that corresponds thereto with the contact regions 58 between the well region 59 and the trench source structure 54. Each of the well regions 59 may be formed as a band extending along a corresponding one of the trench source structures 54. Each of the well regions 59 covers the sidewall and the bottom wall of each of the trench source structures 54, and is electrically connected to the body region 48.

Referring to FIG. 15, the wide bandgap semiconductor device 1G includes a p-type outer contact region 60 formed at the surface layer portion of the second semiconductor region 7 in the outer surface 42. Preferably, the outer contact region 60 has a p-type impurity concentration exceeding the p-type impurity concentration of the body region 48. The outer contact region 60 is formed at an interval from a peripheral edge of the active surface 41 and from a peripheral edge of the outer surface 42 in a plan view.

The outer contact region 60 is formed as a band extending along the active surface 41 in a plan view. In this embodiment, the outer contact region 60 is formed in an annular shape (in detail, quadrangular annular shape) surrounding the active surface 41 in a plan view. The outer contact region 60 is formed at an interval from the bottom portion of the second semiconductor region 7 toward the outer surface 42. The outer contact region 60 is positioned on the bottom portion side of the second semiconductor region 7 with respect to a bottom wall of the trench gate structures 50.

The wide bandgap semiconductor device 1G includes a p-type outer well region 61 formed at a surface layer portion of the outer surface 42. The outer well region 61 has a p-type impurity concentration less than the p-type impurity concentration of the outer contact region 60. Preferably, the p-type impurity concentration of the outer well region 61 is substantially equal to the p-type impurity concentration of the well region 59. The outer well region 61 is formed in a region between the peripheral edge of the active surface 41 and the outer contact region 60 in a plan view.

The outer well region 61 is formed as a band extending along the active surface 41 in a plan view. In this embodiment, the outer well region 61 is formed in an annular shape (in detail, quadrangular annular shape) surrounding the active surface 41 in a plan view. The outer well region 61 is electrically connected to the outer contact region 60. In this embodiment, the outer well region 61 extends from the outer surface 42 toward the first to fourth connecting surfaces 43A to 43D, and covers the first to fourth connecting surfaces 43A to 43D in the chip 2.

The outer well region 61 is formed deeper than the outer contact region 60. The outer well region 61 is formed at an interval from the bottom portion of the second semiconductor region 7 toward the outer surface 42. The outer well region 61 is positioned on the bottom portion side of the second semiconductor region 7 with respect to the bottom wall of the trench gate structures 50. The outer well region 61 is electrically connected to the body region 48 in the surface layer portion of the active surface 41.

The wide bandgap semiconductor device 1G includes at least one (preferably, not less than two and not more than twenty) p-type field region 62 formed in a region between the outer contact region 60 and the peripheral edge of the outer surface 42 in the surface layer portion of the outer surface 42. In this embodiment, the wide bandgap semiconductor device 1G includes five field regions 62. The field regions 62 relax an electric field inside the chip 2 in the outer surface 42. The number, the width, the depth, the p-type impurity concentration, etc., of the field region 62 are arbitrary, and various values can be taken in accordance with an electric field to be relaxed.

The field regions 62 are formed at an interval from the outer contact region 60 side toward the peripheral edge side of the outer surface 42. The field regions 62 are formed as a band extending along the active surface 41 in a plan view. In this embodiment, the field regions 62 are formed in an annular shape (in detail, quadrangular annular shape) surrounding the active surface 41 in a plan view. Hence, the field regions 62 are each formed as an FLR (Field Limiting Ring) region.

The field regions 62 are formed at an interval from the bottom portion of the second semiconductor region 7 toward the outer surface 42. The field regions 62 are positioned on the bottom portion side of the second semiconductor region 7 with respect to the bottom wall of the trench gate structures 50. The field regions 62 are formed deeper than the outer contact region 60. The innermost field region 62 may be connected to the outer contact region 60. The field regions 62 other than the innermost field region 62 may be formed in an electrically floating state.

The wide bandgap semiconductor device 1G includes the first inorganic insulating film 9 mentioned above that covers the first main surface 3. In this embodiment, the first inorganic insulating film 9 covers the active surface 41, the outer surface 42, and the first to fourth connecting surfaces 43A to 43D. The first inorganic insulating film 9 is continuous to the gate insulating film 52 and with the source insulating film 56, and exposes the gate electrode 53 and the source electrode 57. The outer wall of the first inorganic insulating film 9 is formed at an interval inward from the peripheral edge of the outer surface 42, and exposes the second semiconductor region 7 from the peripheral edge portion of the outer surface 42.

As a matter of course, the first inorganic insulating film 9 may cover the outer surface 42 such as to be continuous to the side surface 5 (first to fourth side surfaces 5A to 5D) of the chip 2. In this case, the first inorganic insulating film 9 has an outer wall continuous to the side surface 5 of the chip 2. Preferably, the outer wall of the first inorganic insulating film 9 is constituted of a ground surface having grinding marks. Preferably, the outer wall of the first inorganic insulating film 9 forms a single ground surface together with the side surface 5 (first to fourth side surfaces 5A to 5D) of the chip 2.

The wide bandgap semiconductor device 1G includes a sidewall structure 63 formed on the first inorganic insulating film 9 on the outer surface 42 side such as to cover at least one among the first to fourth connecting surfaces 43A to 43D. In this embodiment, the sidewall structure 63 is formed in an annular shape (quadrangular annular shape) surrounding the active surface 41 in a plan view. The sidewall structure 63 may include an inorganic insulator or polysilicon.

The wide bandgap semiconductor device 1G includes an interlayer insulating film 64 formed on the first inorganic insulating film 9. The interlayer insulating film 64 covers the active surface 41, the outer surface 42, and the first to fourth connecting surfaces 43A to 43D with the first inorganic insulating film 9 between the interlayer insulating film 64 and each of the active surface 41, the outer surface 42, and the first to fourth connecting surfaces 43A to 43D. The interlayer insulating film 64 covers the first inorganic insulating film 9 with the sidewall structure 63 between the interlayer insulating film 64 and the first inorganic insulating film 9. The interlayer insulating film 64 may include at least one among a silicon oxide film, a silicon nitride film, and a silicon oxynitride film. An outer wall of the interlayer insulating film 64 is formed at an interval inward from the peripheral edge of the outer surface 42 in the same way as the outer wall of the first inorganic insulating film 9, and exposes the second semiconductor region 7 from the peripheral edge portion of the outer surface 42.

As a matter of course, the outer wall of the interlayer insulating film 64 may be continuous to the side surface 5 (first to fourth side surfaces 5A to 5D) of the chip 2. In this case, preferably, the outer wall of the interlayer insulating film 64 is constituted of a ground surface having grinding marks. Preferably, the outer wall of the interlayer insulating film 64 forms a single ground surface together with the side surface 5 (first to fourth side surfaces 5A to 5D) of the chip 2.

The wide bandgap semiconductor device 1G includes a plurality of first main surface electrodes 11 formed on the first main surface 3 (on the interlayer insulating film 64). The first main surface electrodes 11 each have a laminated structure including the first main surface electrode film 12 and the second main surface electrode film 13 that are laminated in that order from the chip 2 side in the same way as in the first embodiment. The first main surface electrodes 11 include a gate main surface electrode 65 and a source main surface electrode 67.

A gate potential is to be input to the gate main surface electrode 65 from the outside. The gate main surface electrode 65 is arranged on the active surface 41, and is not arranged on the outer surface 42. In this embodiment, the gate main surface electrode 65 is arranged in a region adjacent to a central portion of the first connecting surface 43A in a peripheral edge portion of the active surface 41. In this embodiment, the gate main surface electrode 65 is formed in a quadrangular shape in a plan view.

The source main surface electrode 67 is arranged on the active surface 41 at an interval from the gate main surface electrode 65. A source potential is to be input to the source main surface electrode 67 from the outside. In this embodiment, the source main surface electrode 67 is formed in a polygonal shape having a concave portion that matches the gate main surface electrode 65 in a plan view. As a matter of course, the source main surface electrode 67 may be formed in a quadrangular shape in a plan view. The source main surface electrode 67 passes through the interlayer insulating film 64 and through the first inorganic insulating film 9, and is electrically connected to the trench source structures 54, to the source region 49, and to the well regions 59.

The wide bandgap semiconductor device 1G includes a gate wiring electrode 66 and a source wiring electrode 68 that are formed on the first main surface 3 (on the interlayer insulating film 64). The gate wiring electrode 66 and the source wiring electrode 68 each have a laminated structure including the first main surface electrode film 12 and the second main surface electrode film 13 that are laminated in that order from the chip 2 side in the same way as the first main surface electrodes 11.

The gate wiring electrode 66 is led out from the gate main surface electrode 65 onto the interlayer insulating film 64. The gate wiring electrode 66 is formed as a band extending along the peripheral edge of the active surface 41 such as to intersect (in detail, orthogonally intersect) the end portion of the trench gate structures 50 in a plan view. The gate wiring electrode 66 passes through the interlayer insulating film 64, and is electrically connected to the trench gate structures 50 (gate electrode 53). The gate wiring electrode 66 transmits a gate potential to be applied to the gate main surface electrode 65 to the trench gate structures 50.

The source wiring electrode 68 is led out from the source main surface electrode 67 onto the interlayer insulating film 64. The source wiring electrode 68 is formed as a band extending along the peripheral edge (first to fourth connecting surfaces 43A to 43D) of the active surface 41 in a region closer to the outer surface 42 than to the gate wiring electrode 66. In this embodiment, the source wiring electrode 68 is formed in an annular shape (in detail, quadrangular annular shape) surrounding the gate main surface electrode 65, the source main surface electrode 67, and the gate wiring electrode 66 in a plan view.

The source wiring electrode 68 covers the sidewall structure 63 with the interlayer insulating film 64 between the source wiring electrode 68 and the sidewall structure 63, and is led out from the active surface 41 side toward the outer surface 42 side. The source wiring electrode 68 is electrically connected to the outer contact region 60 through the interlayer insulating film 64 and through the first inorganic insulating film 9 on the outer surface 42 side. Preferably, the source wiring electrode 68 covers the whole area of the sidewall structure 63 and the whole area of the outer contact region 60 over the entire periphery. The source wiring electrode 68 transmits a source potential to be applied to the source main surface electrode 67 to the outer contact regions 60.

The wide bandgap semiconductor device 1G includes the second inorganic insulating film 14 mentioned above that covers the interlayer insulating film 64 and the first main surface electrodes 11. In this embodiment, the second inorganic insulating film 14 covers the active surface 41, the outer surface 42, and the first to fourth connecting surfaces 43A to 43D with the interlayer insulating film 64, etc., between the second inorganic insulating film 14 and each of the active surface 41, the outer surface 42, and the first to fourth connecting surfaces 43A to 43D. Preferably, the thickness of the second inorganic insulating film 14 is less than the thickness of the interlayer insulating film 64. The second inorganic insulating film 14 covers the interlayer insulating film 64 and the peripheral edge portion of the first main surface electrodes 11, and exposes the inward portion of the first main surface electrodes 11.

In detail, the second inorganic insulating film 14 exposes the inward portion of the gate main surface electrode 65 in a plan view, and covers the peripheral edge portion of the gate main surface electrode 65 over the entire periphery. Also, the second inorganic insulating film 14 exposes the inward portion of the source main surface electrode 67 in a plan view, and covers the peripheral edge portion of the source main surface electrode 67 over the entire periphery. The second inorganic insulating film 14 covers the whole area of the gate wiring electrode 66 and the whole area of the source wiring electrode 68.

The second inorganic insulating film 14 has a first gate inner wall on the gate main surface electrode 65 side, a first source inner wall on the source main surface electrode 67 side, and an outer wall on the outer surface 42 side. The first gate inner wall of the second inorganic insulating film 14 defines a first gate opening 69 that exposes the inward portion of the gate main surface electrode 65. The first gate opening 69 is formed in a quadrangular shape along the peripheral edge of the gate main surface electrode 65 in a plan view.

The first source inner wall of the second inorganic insulating film 14 defines a first source opening 70 that exposes the inward portion of the source main surface electrode 67. The first source opening 70 is formed in a polygonal shape having a concave portion along the concave portion of the source main surface electrode 67 in a plan view. As a matter of course, the first source opening 70 may be formed in a quadrangular shape in a plan view. The outer wall of the second inorganic insulating film 14 is formed at an interval inward from the peripheral edge of the outer surface 42, and defines the dicing street 16 that exposes the second semiconductor region 7 from the peripheral edge portion of the outer surface 42.

As a matter of course, the outer wall of the second inorganic insulating film 14 may be continuous to the side surface 5 (first to fourth side surfaces 5A to 5D) of the chip 2. In this case, preferably, the outer wall of the second inorganic insulating film 14 is constituted of the ground surface having grinding marks. Preferably, the outer wall of the second inorganic insulating film 14 forms a single ground surface together with the side surface 5 (first to fourth side surfaces 5A to 5D) of the chip 2.

The wide bandgap semiconductor device 1G includes the photosensitive resin 17 mentioned above that covers the first main surface electrodes 11. Preferably, the thickness of the photosensitive resin 17 exceeds the thickness of the interlayer insulating film 64. In this embodiment, the photosensitive resin 17 is formed on the second inorganic insulating film 14, and covers the active surface 41, the outer surface 42, and the first to fourth connecting surfaces 43A to 43D with the second inorganic insulating film 14, etc., between the photosensitive resin 17 and each of the active surface 41, the outer surface 42, and the first to fourth connecting surfaces 43A to 43D.

The photosensitive resin 17 covers the peripheral edge portion of the gate main surface electrode 65 and the peripheral edge portion of the source main surface electrode 67 with the second inorganic insulating film 14 between the photosensitive resin 17 and each of the gate main surface electrode 65 and the source main surface electrode 67, and exposes the inward portion of the gate main surface electrode 65 and the inward portion of the source main surface electrode 67. In detail, the photosensitive resin 17 covers the peripheral edge portion of the gate main surface electrode 65 over the entire periphery, and covers the peripheral edge portion of the source main surface electrode 67 over the entire periphery in a plan view. The photosensitive resin 17 covers the whole area of the gate wiring electrode 66 and the whole area of the source wiring electrode 68 with the second inorganic insulating film 14 between the photosensitive resin 17 and each of the gate wiring electrode 66 and the source wiring electrode 68.

The photosensitive resin 17 has a second gate inner wall on the gate main surface electrode 65 side, a second source inner wall on the source main surface electrode 67 side, and an outer wall on the peripheral edge side of the first main surface 3. The second gate inner wall of the photosensitive resin 17 defines a second gate opening 71 that exposes the inward portion of the gate main surface electrode 65. The second gate opening 71 is formed in a quadrangular shape along the peripheral edge of the gate main surface electrode 65 in a plan view. The second source inner wall of the photosensitive resin 17 defines a second source opening 72 that exposes the inward portion of the source main surface electrode 67. The second source opening 72 is formed in a polygonal shape along the peripheral edge of the source main surface electrode 67 in a plan view.

In this embodiment, the photosensitive resin 17 is formed on the second inorganic insulating film 14 such as to expose all of the first gate inner wall, the first source inner wall, and the outer wall of the second inorganic insulating film 14. Therefore, the second gate opening 71 communicates with the first gate opening 69 of the second inorganic insulating film 14. Also, the second source opening 72 communicates with the first source opening 70 of the second inorganic insulating film 14. Also, the outer wall of the photosensitive resin 17 defines the dicing street 16 together with the second inorganic insulating film 14.

If the outer wall of the second inorganic insulating film 14 is continuous to the side surface 5 (first to fourth side surfaces 5A to 5D) of the chip 2, the outer wall of the photosensitive resin 17 defines the dicing street 16 that exposes the second inorganic insulating film 14. The second gate inner wall of the photosensitive resin 17 may be formed in a curved shape that bulges toward the inward portion side of the gate main surface electrode 65. The second source inner wall of the photosensitive resin 17 may be formed in a curved shape that bulges toward the inward portion side of the source main surface electrode 67. The outer wall of the photosensitive resin 17 may be formed in a curved shape that bulges toward the peripheral edge side of the outer surface 42.

The photosensitive resin 17 may cover at least one among the first gate inner wall, the first source inner wall, and the outer wall of the second inorganic insulating film 14. In other words, the photosensitive resin 17 may have at least one among a portion that directly covers a part of the gate main surface electrode 65, a portion that directly covers a part of the source main surface electrode 67, and a portion that directly covers the peripheral edge portion (second semiconductor region 7) of the outer surface 42.

The wide bandgap semiconductor device 1G includes the thermosetting resin 19 mentioned above that covers the first main surface 3. The thermosetting resin 19 is formed on the photosensitive resin 17, and covers the active surface 41, the outer surface 42, and the first to fourth connecting surfaces 43A to 43D with the photosensitive resin 17, etc., between the thermosetting resin 19 and each of the active surface 41, the outer surface 42, and the first to fourth connecting surfaces 43A to 43D. In this embodiment, the thermosetting resin 19 covers the photosensitive resin 17 such as to expose at least one part of each of the first main surface electrodes 11, and covers the peripheral edge portion of the first main surface electrodes 11 and the second inorganic insulating film 14 with the photosensitive resin 17 between the thermosetting resin 19 and each of the first main surface electrode 11 and the second inorganic insulating film 14.

In detail, the thermosetting resin 19 covers the peripheral edge portion of the gate main surface electrode 65 with the photosensitive resin 17 between the thermosetting resin 19 and the gate main surface electrode 65 over the entire periphery in a plan view. Also, the thermosetting resin 19 covers the peripheral edge portion of the source main surface electrode 67 with the photosensitive resin 17 between the thermosetting resin 19 and the source main surface electrode 67 over the entire periphery in a plan view. The thermosetting resin 19 covers the whole area of the gate wiring electrode 66 and the whole area of the source wiring electrode 68 with the photosensitive resin 17 between the thermosetting resin 19 and each of the gate wiring electrode 66 and the source wiring electrode 68.

In this embodiment, the thermosetting resin 19 exposes the second gate inner wall and the second source inner wall of the photosensitive resin 17, and covers the outer wall of the photosensitive resin 17. The thermosetting resin 19 covers the dicing street 16 defined by the photosensitive resin 17 (second inorganic insulating film 14) in the peripheral edge portion of the outer surface 42. The thermosetting resin 19 directly covers the second semiconductor region 7 exposed from the outer surface 42 in the dicing street 16.

The thermosetting resin 19 has the resin main surface 20, the resin inner walls 21, and the resin side surface 22. The resin main surface 20 and the resin side surface 22 are formed in the same way as in the first embodiment. In this embodiment, the resin inner walls 21 define the pad openings 23 that expose the first main surface electrodes 11, respectively. In detail, the resin inner walls 21 include a gate resin inner wall 73 and a source resin inner wall 74.

The gate resin inner wall 73 defines a gate pad opening 75 (pad opening 23) that exposes the inward portion of the gate main surface electrode 65 in the inward portion of the resin main surface 20. The gate pad opening 75 is divisionally formed on the photosensitive resin 17, and communicates with the first gate opening 69 of the second inorganic insulating film 14 and with the second gate opening 71 of the photosensitive resin 17. The gate pad opening 75 is formed in a quadrangular shape along the peripheral edge of the gate main surface electrode 65 in a plan view. Preferably, the gate resin inner wall 73 is constituted of a smooth surface having no grinding marks.

The source resin inner wall 74 defines a source pad opening 76 (pad opening 23) that exposes the inward portion of the source main surface electrode 67 in the inward portion of the resin main surface 20. The source pad opening 76 is divisionally formed on the photosensitive resin 17, and communicates with the first source opening 70 of the second inorganic insulating film 14 and with the second source opening 72 of the photosensitive resin 17. The source pad opening 76 is formed in a quadrangular shape along the peripheral edge of the source main surface electrode 67 in a plan view. Preferably, the source resin inner wall 74 is constituted of a smooth surface having no grinding marks.

The resin inner walls 21 (gate resin inner wall 73 and source resin inner wall 74) each have an upper end portion (opening end) on the resin main surface 20 side and a lower end portion on the chip 2 side (photosensitive resin 17 side) in the same way as in the first embodiment. The lower end portion of each of the resin inner walls 21 is hollowed along the outside surface of the photosensitive resin 17, and forms the gap 24 with the photosensitive resin 17. In detail, the resin inner walls 21 each have the first wall portion 25 on the opening end side and the second wall portion 26 on the lower end portion side. The first wall portion 25 extends in the thickness direction between the opening end and the lower end portion. Preferably, the first wall portion 25 occupies a range of 80% or more of the resin inner wall 21 in a cross-sectional view.

The second wall portion 26 extends in a direction intersecting the first wall portion 25 toward the outer wall of the photosensitive resin 17 between the outside surface of the photosensitive resin 17 and the first wall portion 25, and defines the gap 24 with the outside surface of the photosensitive resin 17. In detail, the second wall portion 26 is obliquely inclined from the first wall portion 25 toward the outside surface of the photosensitive resin 17, and defines the gap 24 having a tapered shape in which the width along the normal direction Z becomes smaller in proportion to a distance receding from the first wall portion 25 (first main surface electrode 11). Preferably, the second wall portion 26 occupies a range less than 20% of the resin inner wall 21 in a cross-sectional view.

The thermosetting resin 19 is composed of the matrix resin 27 and the fillers 28 in the same way as in the first embodiment. The fillers 28 include the small size fillers 28a (first filler), the intermediate size fillers 28b (second filler), and the large size fillers 28c (third filler) in the same way as in the first embodiment. The small size filler 28a has a thickness less than the thickness of the first main surface electrode 11. The intermediate size filler 28b has a thickness exceeding the thickness of the first main surface electrode 11 and being equal to or less than the thickness of the photosensitive resin 17. The large size filler 28c has a thickness exceeding the thickness of the photosensitive resin 17.

The fillers 28 include the filler fragments 29 having broken particle shapes in the surface layer portion of the thermosetting resin 19 in the same way as in the first embodiment. The filler fragments 29 include the first filler fragments 29a formed at the surface layer portion of the resin main surface 20 and the second filler fragments 29b formed at the surface layer portion of the resin side surface 22. The filler fragments 29 each form a part of the grinding marks in the outside surface of the thermosetting resin 19.

The thermosetting resin 19 has almost no filler fragment 29 in the surface layer portion of the resin inner walls 21 (first wall portion 25 and second wall portion 26). In other words, the resin inner walls 21 (pad opening 23) are formed by the matrix resin 27 and by the fillers 28 that are normal. In this case, the percentage of the filler fragments 29 among the fillers 28 forming the resin inner wall 21 is less than the percentage of the normal fillers 28 forming the resin inner wall 21.

The wide bandgap semiconductor device 1G includes the pad electrodes 30 arranged in the pad openings 23. The pad electrodes 30 include a gate pad electrode 80 arranged in the gate pad opening 75 and a source pad electrode 81 arranged in the source pad opening 76. The gate pad electrode 80 enters the second gate opening 71 and the first gate opening 69 from the gate pad opening 75, and is in contact with the gate main surface electrode 65, with the second inorganic insulating film 14, with the photosensitive resin 17, and with the thermosetting resin 19.

In other words, the gate pad electrode 80 is in contact with the matrix resin 27 and with the fillers 28 in the gate pad opening 75. The gate pad electrode 80 is not arranged outside the gate pad opening 75. The gate pad electrode 80 has a planar shape (in this embodiment, quadrangular shape) that matches the gate pad opening 75 in a plan view. The gate pad electrode 80 has a plane area less than the plane area of the gate main surface electrode 65.

The gate pad electrode 80 has a gate electrode surface 80a exposed from the gate pad opening 75. The gate electrode surface 80a is continuous to the resin main surface 20 of the thermosetting resin 19. The gate electrode surface 80a is constituted of a ground surface having grinding marks. The gate electrode surface 80a forms a single ground surface together with the resin main surface 20.

The source pad electrode 81 enters the second source opening 72 and the first source opening 70 from the source pad opening 76, and is in contact with the source main surface electrode 67, with the second inorganic insulating film 14, with the photosensitive resin 17, and with the thermosetting resin 19. In other words, the source pad electrode 81 is in contact with the matrix resin 27 and with the fillers 28 in the source pad opening 76. The source pad electrode 81 is not arranged outside the source pad opening 76. The source pad electrode 81 has a planar shape (in this embodiment, polygonal shape) that matches the source pad opening 76 in a plan view. The source pad electrode 81 has a plane area less than the plane area of the source main surface electrode 67.

The source pad electrode 81 has a source electrode surface 81a exposed from the source pad opening 76. The source electrode surface 81a is continuous to the resin main surface 20 of the thermosetting resin 19. The source electrode surface 81a is constituted of a ground surface having grinding marks. The source electrode surface 81a forms a single ground surface together with the resin main surface 20.

The pad electrodes 30 (gate pad electrode 80 and source pad electrode 81) each have the overhanging portion 30b that rides on the outside surface of the photosensitive resin 17 in the gap 24 in the same way as in the first embodiment. The overhanging portion 30b is in contact with the photosensitive resin 17 and with the thermosetting resin 19 in the gap 24, and has a sectional shape that matches the gap 24.

In other words, the overhanging portion 30b is inclined obliquely downward from the first wall portion 25 side toward the outside surface of the photosensitive resin 17, and is formed in a tapered shape in which a thickness gradually becomes smaller in proportion to a distance receding from the first wall portion 25. The length along the first main surface 3 of the overhanging portion 30b may exceed the thickness of the photosensitive resin 17. As a matter of course, the length of the overhanging portion 30b may be equal to or less than the thickness of the photosensitive resin 17.

The pad electrodes 30 each have a laminated structure including the first pad electrode film 31 and the second pad electrode film 32 that are laminated in that order from the first main surface electrode 11 side in the same way as in the first embodiment. The pad electrodes 30 may have at least one minute void space 33 at a connection portion with the first main surface electrode 11 in the same way as in the first embodiment.

The wide bandgap semiconductor device 1G includes the second main surface electrode 34 that covers the second main surface 4 in the same way as in the first embodiment. The second main surface electrode 34 is electrically connected to the second main surface 4. In detail, the second main surface electrode 34 forms an ohmic contact with the first semiconductor region 6 exposed from the second main surface 4. The second main surface electrode 34 covers the whole area of the second main surface 4 such as to be continuous to the peripheral edge (first to fourth side surfaces 5A to 5D) of the chip 2.

As described above, the same effect as the effect described with respect to the wide bandgap semiconductor device 1A is likewise fulfilled by the wide bandgap semiconductor device 1G.

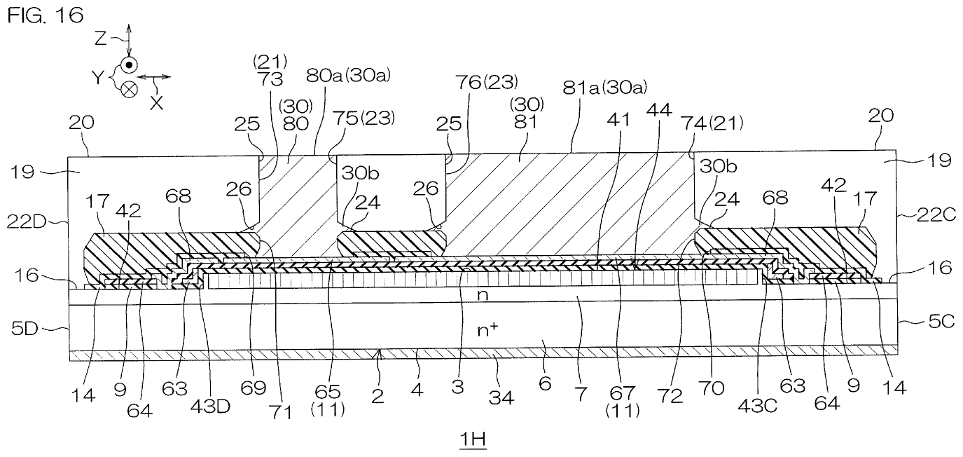

FIG. 16 corresponds to FIG. 12, and is a cross-sectional view showing a wide bandgap semiconductor device 1H according to an eighth embodiment. In the seventh embodiment, an example was described in which the wide bandgap semiconductor device 1G includes the photosensitive resin 17 that exposes the inner peripheral edge portion (inner wall) of the second inorganic insulating film 14. On the other hand, the wide bandgap semiconductor device 1H includes the photosensitive resin 17 that covers the first gate inner wall and the first source inner wall of the second inorganic insulating film 14. In other words, the photosensitive resin 17 includes a portion that directly covers the first main surface electrodes 11.

The resin inner walls 21 (gate resin inner wall 73 and source resin inner wall 74) of the thermosetting resin 19 expose the photosensitive resin 17 and the inward portion of the first main surface electrodes 11 (gate main surface electrode 65 and source main surface electrode 67), and do not expose the second inorganic insulating film 14. The pad electrodes 30 (gate pad electrode 80 and source pad electrode 81) are in contact with a corresponding one of the first main surface electrodes 11, with the photosensitive resin 17, and with the thermosetting resin 19 in a corresponding one of the pad openings 23 (gate pad opening 75 and source pad opening 76), and are not in contact with the second inorganic insulating film 14.

As described above, the same effect as the effect described with respect to the wide bandgap semiconductor device 1A is likewise fulfilled by the wide bandgap semiconductor device 1H.

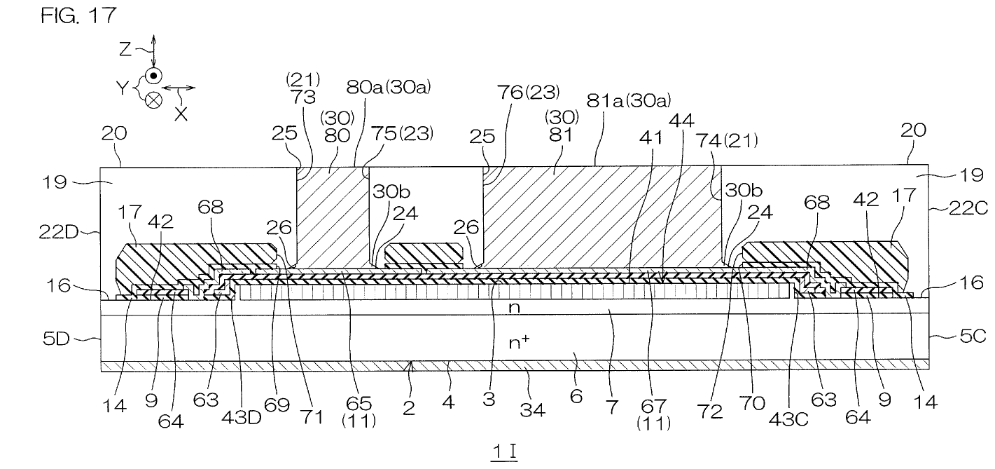

FIG. 17 corresponds to FIG. 12, and is a cross-sectional view showing a wide bandgap semiconductor device 1I according to a ninth embodiment. In the seventh embodiment, an example was described in which the thermosetting resin 19 exposes the first gate inner wall and the first source inner wall of the second inorganic insulating film 14 and the second gate inner wall and the second source inner wall of the photosensitive resin 17.

On the other hand, the wide bandgap semiconductor device 1I includes the thermosetting resin 19 that covers the first gate inner wall and the first source inner wall of the second inorganic insulating film 14 and the second gate inner wall and the second source inner wall of the photosensitive resin 17. In other words, the thermosetting resin 19 includes a portion that directly covers the first main surface electrodes 11.

The resin inner walls 21 (pad opening 23) each expose only a corresponding one of the first main surface electrodes 11, and expose neither the second inorganic insulating film 14 nor the photosensitive resin 17. In this embodiment, the lower end portion of each of the resin inner walls 21 forms the gap 24 with a corresponding one of the first main surface electrodes 11. The pad electrodes 30 are in contact with a corresponding one of the first main surface electrodes 11 and with the thermosetting resin 19 in a corresponding one of the pad openings 23, and are in contact with neither the second inorganic insulating film 14 nor the photosensitive resin 17.

As described above, the same effect as the effect described with respect to the wide bandgap semiconductor device 1A is likewise fulfilled by the wide bandgap semiconductor device 1I. As a matter of course, the form of the thermosetting resin 19 according to the ninth embodiment may be applied to the eighth embodiment.

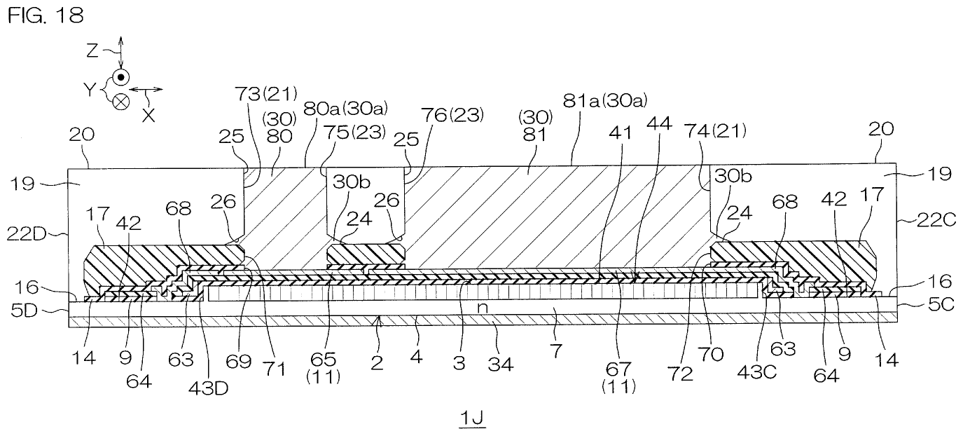

FIG. 18 corresponds to FIG. 12, and is a cross-sectional view showing a wide bandgap semiconductor device 1J according to a tenth embodiment. In the seventh embodiment, an example was described in which the chip 2 has a laminated structure including the first semiconductor region 6 (wide bandgap semiconductor substrate) and the second semiconductor region 7 (wide bandgap semiconductor epitaxial layer) that are formed in that order from the second main surface 4 side. On the other hand, the wide bandgap semiconductor device 1J does not have the first semiconductor region 6 (wide bandgap semiconductor substrate), and includes the chip 2 having a single layer structure constituted of the second semiconductor region 7 (wide bandgap semiconductor epitaxial layer).

As described above, the same effect as the effect described with respect to the wide bandgap semiconductor device 1A is likewise fulfilled by the wide bandgap semiconductor device 1J. Also, with the wide bandgap semiconductor device 1J, it is possible to reduce the resistance value of the first semiconductor region 6, and therefore it is possible to reduce the resistance value of the entirety of the chip 2. Also, the chip 2 is supported by the thermosetting resin 19, and therefore it is possible to supplement the strength of the chip 2, which has been thinned, by means of the thermosetting resin 19. Therefore, it is possible to provide the wide bandgap semiconductor device 1J capable of improving electrical properties while raising reliability. As a matter of course, the form of the chip 2 according to the tenth embodiment may be applied to the eighth and ninth embodiments.

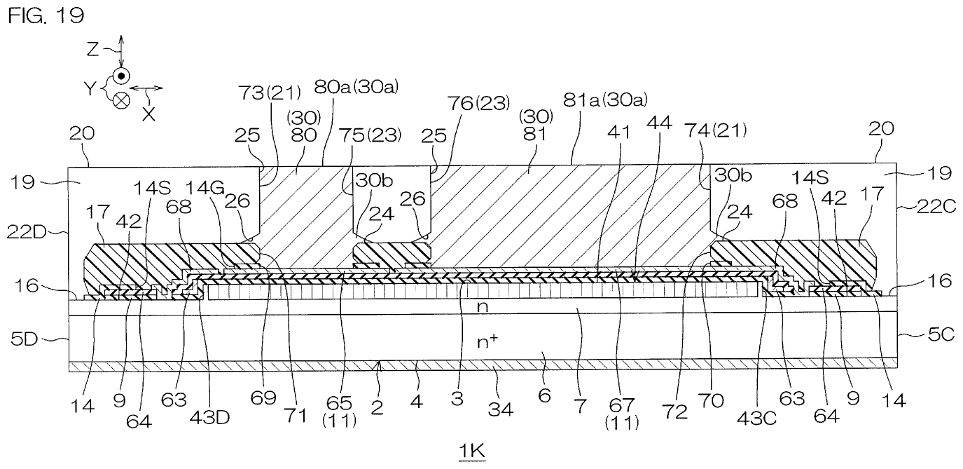

FIG. 19 corresponds to FIG. 12, and is a cross-sectional view showing a wide bandgap semiconductor device 1K according to an eleventh embodiment. In the seventh embodiment, an example was described in which the second inorganic insulating film 14 covers the electrode sidewall of the gate main surface electrode 65 and the electrode sidewall of the source main surface electrode 67. On the other hand, the wide bandgap semiconductor device 1K includes the second inorganic insulating film 14 which has a gate removed portion 14G exposing the electrode sidewall of the gate main surface electrode 65 and a source removed portion 14S exposing the electrode sidewall of the source main surface electrode 67, and that partially covers the gate main surface electrode 65 and the source main surface electrode 67. A structure of the wide bandgap semiconductor device 1K shall be hereinafter described in detail.

The second inorganic insulating film 14 covers the gate main surface electrode 65, the source main surface electrode 67, and the interlayer insulating film 64 in the same way as in the seventh embodiment, and has the first gate inner wall on the gate main surface electrode 65 side, the first source inner wall on the source main surface electrode 67 side, and the outer wall on the outer surface 42 side. The first gate inner wall defines the first gate opening 69 that exposes the inward portion of the gate main surface electrode 65. The first source inner wall defines the first source opening 70 that exposes the inward portion of the source main surface electrode 67. The outer wall is formed at an interval inward from the peripheral edge of the outer surface 42, and defines the dicing street 16 that exposes the second semiconductor region 7.

In this embodiment, the second inorganic insulating film 14 includes at least one gate removed portion 14G that exposes the electrode sidewall of the gate main surface electrode 65 between the gate main surface electrode 65 and the interlayer insulating film 64. In detail, the gate removed portion 14G is formed at an interval from the first gate inner wall and from the outer wall, and exposes the peripheral edge portion of the gate main surface electrode 65 and a part of the interlayer insulating film 64.

If the second inorganic insulating film 14 has a single gate removed portion 14G, the single gate removed portion 14G may be formed as a band extending along the peripheral edge portion of the gate main surface electrode 65 in a plan view, and may partially expose the peripheral edge portion of the gate main surface electrode 65. Also, the single gate removed portion 14G may be formed in an annular shape extending along the peripheral edge portion of the gate main surface electrode 65, and may expose the peripheral edge portion of the gate main surface electrode 65 over the entire periphery.

If the second inorganic insulating film 14 has a plurality of gate removed portions 14G, the gate removed portions 14G may be arranged at an interval from each other along the peripheral edge portion of the gate main surface electrode 65. In this case, the gate removed portions 14G may be arranged in a dot manner in a plan view, or may be each formed as a band extending along the peripheral edge portion of the gate main surface electrode 65.

Also, the gate removed portions 14G may be arranged at an interval from each other from the peripheral edge portion toward the inward portion of the gate main surface electrode 65. In this case, the gate removed portions 14G may be arranged in a dot manner in a plan view, or may be each formed as a band or in an annular shape extending along the peripheral edge portion of the gate main surface electrode 65. In this case, it suffices that at least one gate removed portion 14G exposes the electrode sidewall (peripheral edge portion) of the gate main surface electrode 65.

In this embodiment, the gate removed portion 14G also exposes the electrode sidewall of the gate wiring electrode 66. Preferably, the gate removed portion 14G exposes the whole area of the gate wiring electrode 66. In other words, preferably, the second inorganic insulating film 14 does not cover the gate wiring electrode 66.

In this embodiment, the second inorganic insulating film 14 includes at least one source removed portion 14S that exposes the electrode sidewall of the source main surface electrode 67 between the source main surface electrode 67 and the interlayer insulating film 64. In detail, the source removed portion 14S is formed at an interval from the first source inner wall and from the outer wall, and exposes the peripheral edge portion of the source main surface electrode 67 and a part of the interlayer insulating film 64.

If the second inorganic insulating film 14 has the single source removed portion 14S, the single source removed portion 14S may be formed as a band extending along the peripheral edge portion of the source main surface electrode 67 in a plan view, and may partially expose the peripheral edge portion of the source main surface electrode 67. Also, the single source removed portion 14S may be formed in an annular shape extending along the peripheral edge portion of the source main surface electrode 67, and may expose the peripheral edge portion of the source main surface electrode 67 over the entire periphery.

If the second inorganic insulating film 14 has a plurality of source removed portions 14S, the source removed portions 14S may be arranged at an interval from each other along the peripheral edge portion of the source main surface electrode 67. In this case, the source removed portions 14S may be arranged in a dot manner in a plan view, or may be each formed as a band extending along the peripheral edge portion of the source main surface electrode 67.

Also, the source removed portions 14S may be arranged at an interval from each other from the peripheral edge portion toward the inward portion of the source main surface electrode 67. In this case, the source removed portions 14S may be arranged in a dot manner in a plan view, or may be each formed as a band or in an annular shape extending along the peripheral edge portion of the source main surface electrode 67. In this case, it suffices that at least one source removed portion 14S exposes the electrode sidewall (peripheral edge portion) of the source main surface electrode 67.

In this embodiment, the source removed portion 14S also exposes the electrode sidewall of the source wiring electrode 68. Preferably, the source removed portion 14S exposes the whole area of the source wiring electrode 68. In other words, preferably, the second inorganic insulating film 14 does not cover the source wiring electrode 68. Also, preferably, the source removed portion 14S exposes a stepped portion (first to fourth connecting surfaces 43A to 43D) formed between the active surface 41 and the outer surface 42.

In this embodiment, the photosensitive resin 17 enters the gate removed portion 14G from above the second inorganic insulating film 14. The photosensitive resin 17 covers the electrode sidewall of the gate main surface electrode 65 and the electrode sidewall of the gate wiring electrode 66 in the gate removed portion 14G. In this embodiment, the photosensitive resin 17 directly covers the peripheral edge portion of the gate main surface electrode 65, the whole area of the gate wiring electrode 66, and a part of the interlayer insulating film 64 in the gate removed portion 14G. In other words, the photosensitive resin 17 has a resin gate anchor portion positioned in the gate removed portion 14G.

In this embodiment, the photosensitive resin 17 enters the source removed portion 14S from above the second inorganic insulating film 14. The photosensitive resin 17 covers the electrode sidewall of the source main surface electrode 67 and the electrode sidewall of the source wiring electrode 68 in the source removed portion 14S. In this embodiment, the photosensitive resin 17 directly covers the peripheral edge portion of the source main surface electrode 67, the whole area of the source wiring electrode 68, and a part of the interlayer insulating film 64 in the source removed portion 14S. In other words, the photosensitive resin 17 has a resin source anchor portion positioned in the source removed portion 14S.

In this embodiment, the thermosetting resin 19 includes a portion that covers the gate removed portion 14G and the source removed portion 14S of the second inorganic insulating film 14 with the photosensitive resin 17 between the thermosetting resin 19 and each of the gate removed portion 14G and the source removed portion 14S. In other words, the thermosetting resin 19 includes a portion that covers the peripheral edge portion of the gate main surface electrode 65 and the gate wiring electrode 66 with only the photosensitive resin 17, without the second inorganic insulating film 14, between the thermosetting resin 19 and each of the gate main surface electrode 65 and the gate wiring electrode 66. Also, the thermosetting resin 19 includes a portion that covers the peripheral edge portion of the source main surface electrode 67 and the source wiring electrode 68 with only the photosensitive resin 17, without the second inorganic insulating film 14, between the thermosetting resin 19 and each of the source main surface electrode 67 and the source wiring electrode 68. Preferably, the thermosetting resin 19 covers the whole area of the gate removed portion 14G and the whole area of the source removed portion 14S in a plan view and in a cross-sectional view.

As described above, the same effect as the effect described with respect to the wide bandgap semiconductor device 1A is likewise fulfilled by the wide bandgap semiconductor device 1K. Also, the wide bandgap semiconductor device 1K includes the second inorganic insulating film 14 having the gate removed portion 14G that exposes the electrode sidewall of the gate main surface electrode 65. With this structure, it is possible to reduce peel-off starting points of the second inorganic insulating film 14 caused by the thermal expansion of the gate main surface electrode 65. Therefore, it is possible to provide the wide bandgap semiconductor device 1K capable of improving reliability.

Preferably, the wide bandgap semiconductor device 1K includes the photosensitive resin 17 covering the electrode sidewall of the gate main surface electrode 65 in the gate removed portion 14G. With this structure, it is possible to reduce the peel-off starting points of the gate main surface electrode 65 in a structure in which the second inorganic insulating film 14 has the gate removed portion 14G. Therefore, it is possible to provide the wide bandgap semiconductor device 1K capable of improving reliability.

Preferably, the wide bandgap semiconductor device 1K has the thermosetting resin 19 including a part that covers the gate removed portion 14G with the photosensitive resin 17 between the thermosetting resin 19 and the gate removed portion 14G. With this structure, it is possible to reduce the peel-off starting points of the gate main surface electrode 65 by means of the photosensitive resin 17 and the thermosetting resin 19 in a structure in which the second inorganic insulating film 14 has the gate removed portion 14G.

Also, the wide bandgap semiconductor device 1K includes the second inorganic insulating film 14 having the source removed portion 14S that exposes the electrode sidewall of the source main surface electrode 67. With this structure, it is possible to reduce the peel-off starting points of the second inorganic insulating film 14 caused by the thermal expansion of the source main surface electrode 67. Therefore, it is possible to provide the wide bandgap semiconductor device 1K capable of improving reliability.

Preferably, the wide bandgap semiconductor device 1K includes the photosensitive resin 17 covering the electrode sidewall of the source main surface electrode 67 in the source removed portion 14S. With this structure, it is possible to reduce the peel-off starting points of the source main surface electrode 67 by means of the photosensitive resin 17 and the thermosetting resin 19 in a structure in which the second inorganic insulating film 14 has the source removed portion 14S.

Preferably, the wide bandgap semiconductor device 1K has the thermosetting resin 19 including a part that covers the source removed portion 14S with the photosensitive resin 17 between the thermosetting resin 19 and the source removed portion 14S. With this structure, it is possible to reduce the peel-off starting points of the source main surface electrode 67 by means of the photosensitive resin 17 and the thermosetting resin 19 in a structure in which the second inorganic insulating film 14 has the source removed portion 14S.

Preferably, the second inorganic insulating film 14 has the gate removed portion 14G that exposes the electrode sidewall of the gate wiring electrode 66. With this structure, it is possible to reduce the peel-off starting points of the second inorganic insulating film 14 caused by the thermal expansion of the gate wiring electrode 66. Preferably, the second inorganic insulating film 14 has the source removed portion 14S that exposes the electrode sidewall of the source wiring electrode 68. With this structure, it is possible to reduce the peel-off starting points of the second inorganic insulating film 14 caused by the thermal expansion of the source wiring electrode 68.

As a matter of course, the form of the gate main surface electrode 65, the form of the gate wiring electrode 66, the form of the source main surface electrode 67, the form of the source wiring electrode 68, the form of the second inorganic insulating film 14, the form of the photosensitive resin 17, and the form of the thermosetting resin 19 that are according to the eleventh embodiment may be applied to the eighth to tenth embodiments.

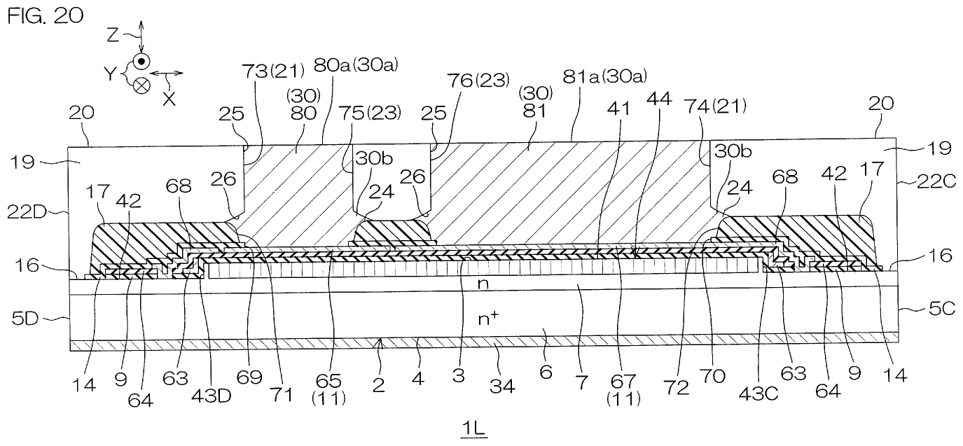

FIG. 20 corresponds to FIG. 12, and is a cross-sectional view showing a wide bandgap semiconductor device 1L according to a twelfth embodiment. In the seventh embodiment, an example was described in which the photosensitive resin 17 has the curved second gate inner wall that bulges toward the inward portion side of the gate main surface electrode 65, the curved second source inner wall that bulges toward the inward portion side of the source main surface electrode 67, and the curved outer wall that bulges toward the peripheral edge side of the outer surface 42.

On the other hand, the wide bandgap semiconductor device 1L includes the photosensitive resin 17 having the second gate inner wall that is inclined obliquely downward toward the inward portion side of the gate main surface electrode 65, the second source inner wall that is inclined obliquely downward toward the inward portion side of the source main surface electrode 67, and the outer wall that is inclined obliquely downward toward the peripheral edge side of the chip 2 (outer surface 42). In other words, the photosensitive resin 17 is formed in a trapezoidal shape (tapered shape) in a cross-sectional view.

As described above, the same effect as the effect described with respect to the wide bandgap semiconductor device 1A is likewise fulfilled by the wide bandgap semiconductor device 1L. Also, with the wide bandgap semiconductor device 1L, it is possible to improve the flowability of the thermosetting resin 19 (matrix resin 27 and fillers 28) with respect to the photosensitive resin 17. Hence, it is possible to suppress the formation of a gap between the thermosetting resin 19 and the photosensitive resin 17. As a matter of course, the form of the photosensitive resin 17 according to the twelfth embodiment may be applied to the eighth to eleventh embodiments.

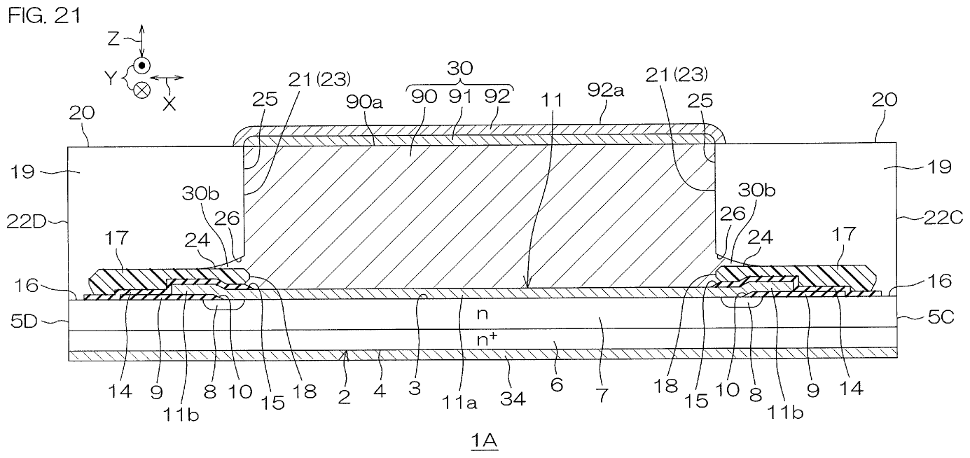

A modification example of the pad electrode 30 is shown below. FIG. 21 corresponds to FIG. 3, and is a cross-sectional view showing a modification example of the pad electrode 30. In the first embodiment, an example was described in which the wide bandgap semiconductor device 1A includes the pad electrode 30 that has a laminated structure including the first pad electrode film 31 and the second pad electrode film 32 that are laminated in that order from the first main surface electrode 11 side.

However, the pad electrode 30 may have a laminated structure including a nickel film 90, a palladium film 91, and a gold film 92 that are laminated in that order from the first main surface electrode 11 side as shown in FIG. 21. The nickel film 90, the palladium film 91, and the gold film 92 may be formed by the electrolytic plating method and/or the electroless plating method.

The nickel film 90 may be formed with a thickness that is in contact with the resin inner wall 21 by filling the first opening 15 and the second opening 18 therewith. The nickel film 90 may have an electrode surface 90a exposed from the thermosetting resin 19 (pad opening 23). The electrode surface 90a may extend along the first main surface 3. The electrode surface 90a may extend in substantially parallel to the first main surface 3. The electrode surface 90a may be continuous to the resin main surface 20. The electrode surface 90a may be constituted of a ground surface having grinding marks. The electrode surface 90a may form a single ground surface together with the resin main surface 20. The nickel film 90 may have the overhanging portion 30b that rides on the outside surface of the photosensitive resin 17 in the gap 24.

The palladium film 91 may cover the nickel film 90 such as to protrude from the resin main surface 20. The palladium film 91 may have a covering portion that covers a part of the thermosetting resin 19 (resin main surface 20) at an interval from the resin side surface 22. The covering portion of the palladium film 91 may cover at least one filler fragment 29 (first filler fragment 29a).

The gold film 92 may cover the palladium film 91 such as to protrude from the resin main surface 20. The gold film 92 may have a covering portion that covers a part of the thermosetting resin 19 (resin main surface 20) at an interval from the resin side surface 22. The covering portion of the gold film 92 may cover at least one filler fragment 29 (first filler fragment 29a). The gold film 92 may have an electrode surface 92a exposed from the thermosetting resin 19 (resin main surface 20). In this case, the electrode surface 92a may be a smooth surface that has no grinding marks.

As described above, the same effect as the effect described with respect to the wide bandgap semiconductor device 1A is likewise fulfilled when the semiconductor device has the pad electrode 30 according to the modification example. In this embodiment, an example was shown in which the palladium film 91 and the gold film 92 are positioned outside the pad opening 23. However, all of the nickel film 90, the palladium film 91, and the gold film 92 may be arranged in the pad opening 23. In this case, the electrode surface 92a of the gold film 92 may be a smooth surface that has no grinding marks.

Also, the pad electrode 30 is not necessarily required to include the palladium film 91, and may include the nickel film 90 and the gold film 92 that are laminated in that order from the first main surface electrode 11 side. As a matter of course, the pad electrode 30 according to the modification example may be applied to the pad electrode 30 (including the gate pad electrode 80 and the source pad electrode 81) according to the second to twelfth embodiments.

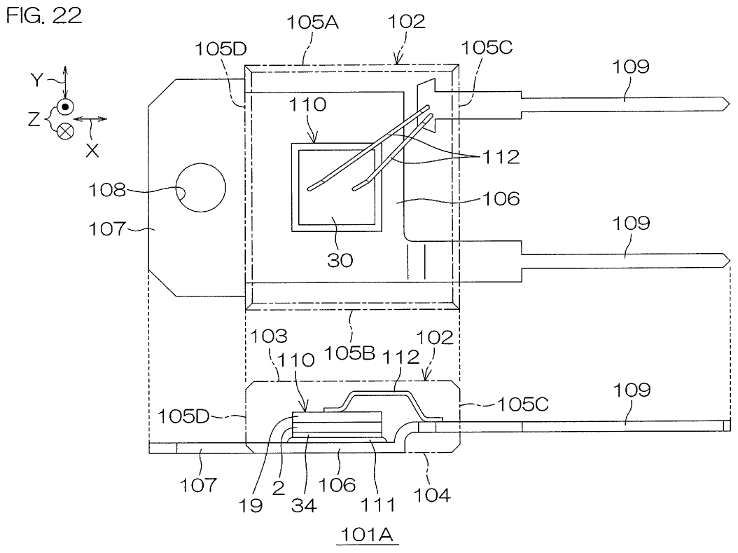

A mode example of a package in which the wide bandgap semiconductor devices 1A to 1L according to the first to twelfth embodiments are each mounted is shown below. FIG. 22 is a plan view showing a semiconductor package 101A in which the wide bandgap semiconductor devices 1A to 1F according to the first to sixth embodiments are each mounted.

The semiconductor package 101A includes a rectangular-parallelepiped-shaped package main body 102. The package main body 102 is constituted of a molded resin that contains a matrix resin (for example, epoxy resin) and a plurality of fillers. The package main body 102 has a first surface 103 on one side, a second surface 104 on the other side, and first to fourth sidewalls 105A to 105D that connect the first surface 103 and the second surface 104 together.

The first surface 103 and the second surface 104 are each formed in a quadrangular shape in a plan view seen from their normal directions Z. The first sidewall 105A and the second sidewall 105B extend in the first direction X, and face the second direction Y perpendicular to the first direction X. The third sidewall 105C and the fourth sidewall 105D extend in the second direction Y, and face the first direction X.

The semiconductor package 101A includes a metal plate 106 (conductive plate) arranged in the package main body 102. The metal plate 106 is formed in a quadrangular shape (in detail, rectangular shape) in a plan view. The metal plate 106 includes a lead-out plate portion 107 that is led out from the fourth sidewall 105D to the outside of the package main body 102. The lead-out plate portion 107 may be referred to as a “heat spreader portion.” The lead-out plate portion 107 has a circular through hole 108. The metal plate 106 may be exposed from the second surface 104.

The semiconductor package 101A includes a plurality of (in this embodiment, two) terminal electrodes 109 led out from the inside of the package main body 102. The terminal electrodes 109 are arranged on the third sidewall 105C side. The terminal electrodes 109 are each formed as a band extending in the orthogonal direction (i.e., second direction Y) of the third sidewall 105C. One of the terminal electrodes 109 is arranged at an interval from the metal plate 106, and the other terminal electrode 109 is formed integrally with the metal plate 106.

The semiconductor package 101A includes an SBD chip 110 arranged on the metal plate 106 in the package main body 102. The SBD chip 110 is constituted of any one of the wide bandgap semiconductor devices 1A to 1F according to the first to sixth embodiments. The second main surface electrode 34 of the SBD chip 110 is electrically connected to the metal plate 106. The semiconductor package 101A includes a conductive bonding material 111. The conductive bonding material 111 may include a solder or a metal paste (preferably, solder). The conductive bonding material 111 is interposed between the second main surface electrode 34 and the metal plate 106, and connects the SBD chip 110 to the metal plate 106.

The semiconductor package 101A includes at least one lead wire 112 (conductive connecting member) that connects the terminal electrode 109 and the pad electrode 30 of the SBD chip 110 together in the package main body 102. The lead wire 112 may be referred to as “bonding wires.” The lead wire 112 may include at least one among a gold wire, a copper wire, and an aluminum wire.

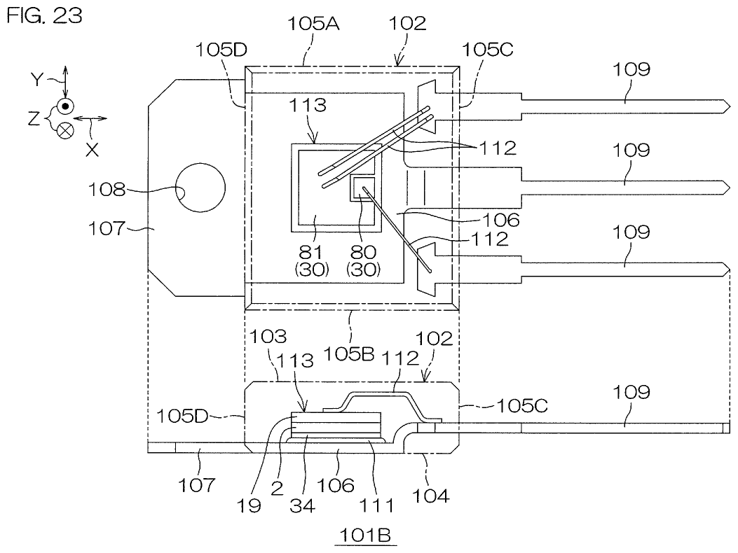

FIG. 23 is a plan view showing a semiconductor package 101B in which the wide bandgap semiconductor devices 1G to 1L according to the seventh to twelfth embodiments are each mounted. Referring to FIG. 23, the semiconductor package 101B includes the package main body 102, the metal plate 106, a plurality of terminal electrodes 109 (in this embodiment, three), a MISFET chip 113, the conductive bonding material 111, and a plurality of lead wires 112. Points in which the semiconductor package 101B differs from the semiconductor package 101A shall be hereinafter described.

The terminal electrodes 109 on both sides among the terminal electrodes 109 are each arranged at an interval from the metal plate 106, and the terminal electrode 109 arranged at the center is formed integrally with the metal plate 106. The terminal electrode 109 connected to the metal plate 106 is arbitrarily arranged. The MISFET chip 113 is constituted of any one of the wide bandgap semiconductor devices 1G to 1L according to the seventh to twelfth embodiments.

The second main surface electrode 34 of the MISFET chip 113 is electrically connected to the metal plate 106. The conductive bonding material 111 is interposed between the second main surface electrode 34 and the metal plate 106, and connects the MISFET chip 113 to the metal plate 106. The lead wires 112 are each connected to the terminal electrodes 109, to the gate pad electrode 80, and to the source pad electrode 81.

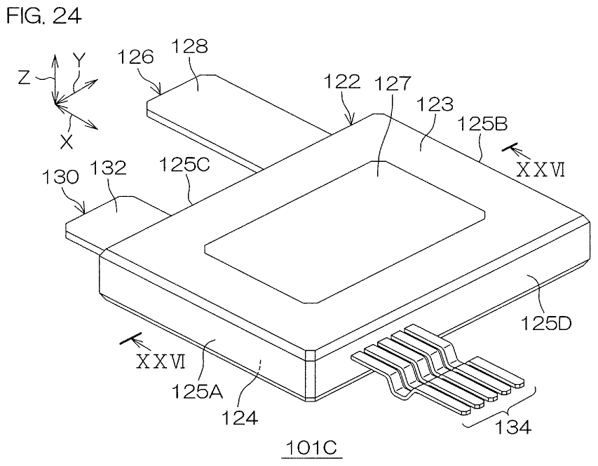

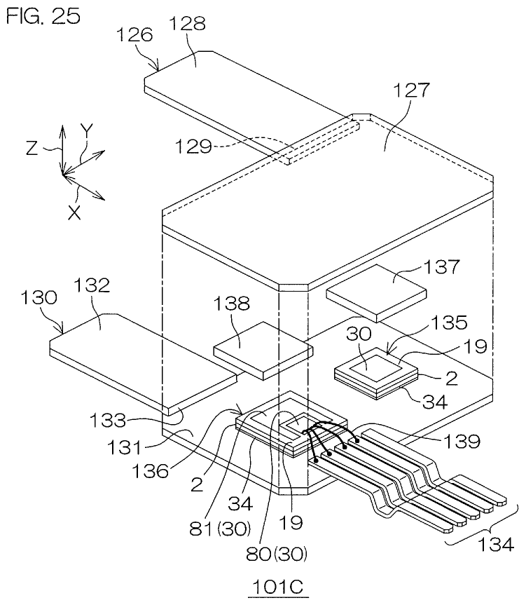

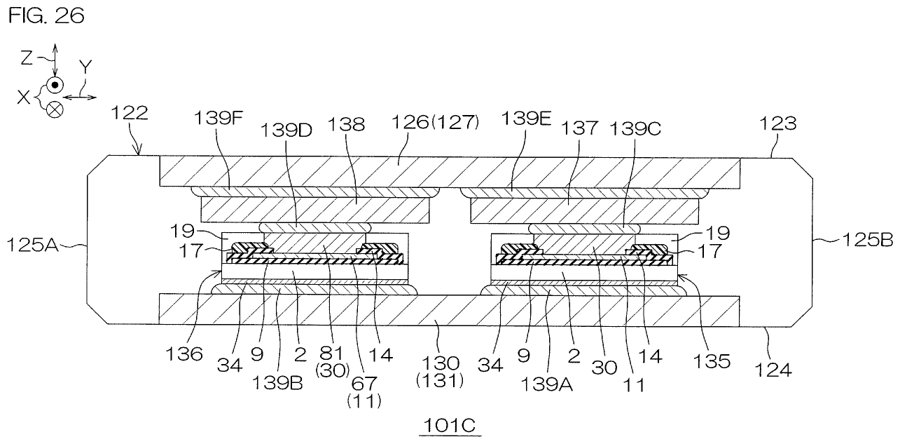

FIG. 24 is a perspective view showing a semiconductor package 101C in which the wide bandgap semiconductor devices 1A to 1F according to the first to sixth embodiments and the wide bandgap semiconductor devices 1G to 1L according to the seventh to twelfth embodiments are each mounted. FIG. 25 is an exploded perspective view of the semiconductor package 101C shown in FIG. 24. FIG. 26 is a cross-sectional view taken along line XXVI-XXVI shown in FIG. 24.

Referring to FIG. 24 to FIG. 26, the semiconductor package 101C includes a rectangular-parallelepiped-shaped package main body 122. The package main body 122 is constituted of a molded resin that contains a matrix resin (for example, epoxy resin) and a plurality of fillers. The package main body 122 has a first surface 123 on one side, a second surface 124 on the other side, and first to fourth sidewalls 125A to 125D that connect the first surface 123 and the second surface 124 together.

The first surface 123 and the second surface 124 are each formed in a quadrangular shape (in this embodiment, rectangular shape) in a plan view seen from their normal directions Z. The first sidewall 125A and the second sidewall 125B extend in the first direction X along the first surface 123, and face the second direction Y. The first sidewall 125A and the second sidewall 125B form the short side of the package main body 122. The third sidewall 125C and the fourth sidewall 125D extend in the second direction Y, and face the first direction X. The third sidewall 125C and the fourth sidewall 125D form the long side of the package main body 122.

The semiconductor package 101C includes a first metal plate 126 (first conductive plate, terminal electrode) arranged inside/outside the package main body 122. The first metal plate 126 is arranged on the first surface 123 side of the package main body 122, and includes a first pad portion 127 and a first terminal portion 128. The first pad portion 127 is formed in a rectangular shape extending in the second direction Y in the package main body 122, and is exposed from the first surface 123.

The first terminal portion 128 is led out as a band extending in the first direction X from the first pad portion 127 such as to pass through the third sidewall 125C. The first terminal portion 128 is arranged on the second sidewall 125B side in a plan view. The first terminal portion 128 is connected to the first pad portion 127 through a first bent portion 129 that is bent from the first surface 123 side toward the second surface 124 side in the package main body 122. The first terminal portion 128 is exposed from the third sidewall 125C at an interval from the first surface 123 toward the second surface 124 side.

The semiconductor package 101C includes a second metal plate 130 (conductive plate, terminal electrode) arranged inside/outside the package main body 122. The second metal plate 130 is arranged on the second surface 124 side of the package main body 122 at an interval from the first metal plate 126 in the normal direction Z, and includes a second pad portion 131 and a second terminal portion 132. The second pad portion 131 is formed in a rectangular shape extending in the second direction Y in the package main body 122, and is exposed from the second surface 124.

The second terminal portion 132 is led out as a band extending in the first direction X from the second pad portion 131 such as to pass through the third sidewall 125C. The second terminal portion 132 is arranged on the first sidewall 125A side in a plan view. The second terminal portion 132 is connected to the second pad portion 131 through a second bent portion 133 that is bent from the second surface 124 side toward the first surface 123 side in the package main body 122. The second terminal portion 132 is exposed from the third sidewall 125C at an interval from the second surface 124 toward the first surface 123 side.

The second terminal portion 132 is led out from a thickness position differing from that of the first terminal portion 128 with respect to the normal direction Z. In this embodiment, the second terminal portion 132 is formed at an interval from the first terminal portion 128 toward the second surface 124 side, and does not face the first terminal portion 128 in the second direction Y. The second terminal portion 132 has a length differing from that of the first terminal portion 128 with respect to the first direction X. The first terminal portion 128 and the second terminal portion 132 are distinguished from each other by their shapes (lengths).

The semiconductor package 101C includes a plurality of (in this embodiment, five) terminal electrodes 134 that are led out from the inside of the package main body 122. In this embodiment, the terminal electrodes 134 are arranged at a thickness position between the first pad portion 127 and the second pad portion 131. The terminal electrodes 134 are exposed from the fourth sidewall 125D on the side opposite to the third sidewall 125C from which the first terminal portion 128 and the second terminal portion 132 are exposed.

The terminal electrodes 134 are arbitrarily arranged. In this embodiment, the terminal electrodes 134 are arranged on the fourth sidewall 125D side such as to be positioned on the same straight line as the second terminal portion 132 in a plan view. The terminal electrodes 134 are each formed as a band extending in the first direction X. The terminal electrodes 134 may, in a portion positioned outside the package main body 122, have a curved portion that is hollowed toward the first surface 123 and/or the second surface 124.

The semiconductor package 101C includes an SBD chip 135 arranged in the package main body 122. The SBD chip 135 is constituted of any one of the wide bandgap semiconductor devices 1A to 1F according to the first to sixth embodiments. The SBD chip 135 is arranged between the first pad portion 127 and the second pad portion 131. The SBD chip 135 is arranged on the second sidewall 125B side in a plan view. The second main surface electrode 34 of the SBD chip 135 is electrically connected to the second pad portion 131.

The semiconductor package 101C includes a MISFET chip 136 arranged in the package main body 122 at an interval from the SBD chip 135. The MISFET chip 136 is constituted of any one of the wide bandgap semiconductor devices 1G to 1L according to the seventh to twelfth embodiments. The MISFET chip 136 is arranged between the first pad portion 127 and the second pad portion 131. The MISFET chip 136 is arranged on the first sidewall 125A side in a plan view. The second main surface electrode 34 of the MISFET chip 136 is electrically connected to the second pad portion 131.

The semiconductor package 101C includes a first conductor spacer 137 (first conductive connecting member) and a second conductor spacer 138 (second conductive connecting member) that are each arranged in the package main body 122. The first conductor spacer 137 is interposed between the SBD chip 135 and the first pad portion 127, and is electrically connected to the SBD chip 135 and to the first pad portion 127.

The second conductor spacer 138 is interposed between the MISFET chip 136 and the first pad portion 127, and is electrically connected to the MISFET chip 136 and to the first pad portion 127. Each of the first and second conductor spacers 137 and 138 may include a metal plate (for example, Cu-based metal plate). In this embodiment, the second conductor spacer 138 is formed structurally independently of the first conductor spacer 137, and yet may be formed integrally with the first conductor spacer 137.

The semiconductor package 101C includes first to sixth conductive bonding materials 139A to 139F. Each of the first to sixth conductive bonding materials 139A to 139F may include a solder or a metal paste (preferably, solder). The first conductive bonding material 139A is interposed between the second main surface electrode 34 of the SBD chip 135 and the second pad portion 131, and connects the SBD chip 135 to the second pad portion 131.

The second conductive bonding material 139B is interposed between the second main surface electrode 34 of the MISFET chip 136 and the second pad portion 131, and connects the MISFET chip 136 to the second pad portion 131. The third conductive bonding material 139C is interposed between the pad electrode 30 of the SBD chip 135 and the first conductor spacer 137, and connects the first conductor spacer 137 to the SBD chip 135.

The fourth conductive bonding material 139D is interposed between the source pad electrode 81 of the MISFET chip 136 and the second conductor spacer 138, and connects the second conductor spacer 138 to the MISFET chip 136. The fifth conductive bonding material 139E is interposed between the first pad portion 127 and the first conductor spacer 137, and connects the first pad portion 127 to the first conductor spacer 137. The sixth conductive bonding material 139F is interposed between the first pad portion 127 and the second conductor spacer 138, and connects the first pad portion 127 to the second conductor spacer 138.

The semiconductor package 101C includes a plurality of lead wires 140 (third conductive connecting member). The lead wires 140 are each connected to the inner end portion of the terminal electrodes 134 and to the gate pad electrode 80 of the MISFET chip 136. The lead wires 140 may include a lead wire 140 connected to an inner end portion of an arbitrary terminal electrode 134 and to the second pad portion 131. The lead wires 140 may be referred to as “bonding wires.” The lead wires 140 may include at least one among a gold wire, a copper wire, and an aluminum wire.

Each of the embodiments mentioned above can be carried out in still other embodiments. For example, in each of the embodiments mentioned above, the first main surface 3 and the second main surface 4 may be each formed by a c-plane of a SiC monocrystal ((0001) plane). In this case, preferably, the first main surface 3 is formed by a silicon plane of the SiC monocrystal, and the second main surface 4 is formed by a carbon plane of the SiC monocrystal.

The first main surface 3 and the second main surface 4 may have an off angle that is inclined at a predetermined angle in a predetermined off direction with respect to the c-plane. Preferably, the off direction is an a-axis direction ([11-20] direction) of the SiC monocrystal. The off angle may be more than 0° and be equal to or less than 10°. Preferably, the off angle is equal to or less than 5°. Particularly preferably, the off angle is not less than 2° and not more than 4.5°.

In each of the embodiments mentioned above, preferably, the first direction X is an m-axis direction ([1-100] direction) of the SiC monocrystal, and the second direction Y is an a-axis direction ([11-20] direction) of the SiC monocrystal. As a matter of course, the first direction X may be an a-axis direction ([11-20] direction) of the SiC monocrystal, and the second direction Y may be an m-axis direction ([1-100] direction) of the SiC monocrystal in each of the embodiments mentioned above.

In each of the embodiments, an example was described in which the chip 2 constituted of a SiC monocrystal is employed. However, a wide bandgap semiconductor chip constituted of a wide bandgap semiconductor other than SiC may be employed. Diamond or GaN (gallium nitride) may be employed as the wide bandgap semiconductor other than SiC.

As a matter of course, the chip 2 according to each of the embodiments mentioned above may be constituted of a Si (silicon) monocrystal. However, in this case, it should be noted that, in consideration of electrical properties of Si (particularly, breakdown voltage), the second semiconductor region 7 (Si epitaxial layer) is required to be formed thick, and therefore, if the thermosetting resin 19 is provided, the size becomes larger as compared to the case of the wide bandgap semiconductor device.

In each of the embodiments, an example was described in which the second inorganic insulating film 14 is formed. However, the second inorganic insulating film 14 is not necessarily required to be provided, and may be removed if necessary. In each of the embodiments, an example was described in which the thermosetting resin 19 defines the gap 24 with the photosensitive resin 17, and the pad electrode 30 has the overhanging portion 30b positioned in the gap 24. However, the thermosetting resin 19 that does not define the gap 24 with the photosensitive resin 17 may be formed, and the pad electrode 30 that does not have the overhanging portion 30b may be formed.

In each of the embodiments, an example was described in which the SBD and the MISFET each of which is an example of a functional device are formed in the mutually different chips 2, respectively. However, the SBD and the MISFET may be formed in mutually different regions, respectively, of the first main surface 3 in the same chip 2.

In each of the embodiments, an embodiment was described in which the first conductivity type is an n-type and in which the second conductivity type is a p-type. However, in each of the embodiments mentioned above, an embodiment may be employed in which the first conductivity type is a p-type and in which the second conductivity type is an n-type. A concrete configuration in this case can be obtained by replacing an n-type region with a p-type region and by replacing a p-type region with an n-type region in the foregoing description and the accompanying drawings.

Examples of features extracted from this description and from the accompanying drawings are shown below. [A1] to [A20] and [B1] to [B21] mentioned below provide a semiconductor device capable of improving reliability. In the following recitation, alphanumeric characters in parentheses represent corresponding components, etc., in the aforementioned embodiments, and yet these are not to the effect that the scope of each clause is limited to the embodiments. In the following clauses, a “wide bandgap semiconductor” may be replaced with a “semiconductor.”

[A1] A wide bandgap semiconductor device (1A to 1L) comprising: a chip (2) that includes a wide bandgap semiconductor and that has a main surface (3); a first main surface electrode (11, 65, 67) arranged on the main surface (3); and a thermosetting resin (19) that includes a matrix resin (27) and a plurality of fillers (28) and that covers the main surface (3) such as to expose a part of the first main surface electrode (11, 65, 67).

[A2] The wide bandgap semiconductor device (1A to 1L) according to A1 or A2, wherein the thermosetting resin (19) is thicker than the first main surface electrode (11, 65, 67).

[A3] The wide bandgap semiconductor device (1A to 1L) according to A2, wherein the fillers (28) include a plurality of first fillers (28a) that are thinner than the first main surface electrode (11, 65, 67) and a plurality of second fillers (28b, 28c) that are thicker than the first main surface electrode (11, 65, 67).

[A4] The wide bandgap semiconductor device (1A to 1L) according to any one of A1 to A3 further comprising: a photosensitive resin (17) covering a peripheral edge portion of the first main surface electrode (11, 65, 67); wherein the thermosetting resin (19) covers the photosensitive resin (17).

[A5] The wide bandgap semiconductor device (1A to 1L) according to A4, wherein the photosensitive resin (17) is thicker than the first main surface electrode (11, 65, 67), and the thermosetting resin (19) is thicker than the photosensitive resin (17).

[A6] The wide bandgap semiconductor device (1A to 1L) according to A5, wherein the fillers (28) include a plurality of large size fillers (28c) that are thicker than the photosensitive resin (17).

[A7] The wide bandgap semiconductor device (1A to 1L) according to any one of A1 to A6, wherein the thermosetting resin (19) is thicker than the chip (2).

[A8] The wide bandgap semiconductor device (1A to 1L) according to any one of A1 to A7, further comprising: a pad electrode (30, 80, 81) that is formed on a part of the first main surface electrode (11, 65, 67) which is exposed from the thermosetting resin (19), and that has an electrode surface (30a, 80a, 81a, 90a, 92a) exposed from the thermosetting resin (19).

[A9] The wide bandgap semiconductor device (1A to 1L) according to A8, wherein the electrode surface (30a, 80a, 81a, 90a) forms a single flat surface together with an outside surface of the thermosetting resin (19).

[A10] The wide bandgap semiconductor device (1A to 1L) according to A8 or A9, wherein the pad electrode (30, 80, 81) has a laminated structure including a first electrode film (31) covering the first main surface electrode (11, 65, 67) and a second electrode film (32) covering the first electrode film (31).

[A11] The wide bandgap semiconductor device (1A to 1L) according to any one of A1 to A10, wherein the fillers (28) include a plurality of filler fragments (29, 29a, 29b) having particle shapes broken in a surface layer portion of the thermosetting resin (19).

[A12] The wide bandgap semiconductor device (1A to 1L) according to any one of A1 to A11, wherein the chip (2) has a side surface (5, 5A to 5D), and the thermosetting resin (19) has a resin side surface (22, 22A to 22D) continuous to the side surface (5, 5A to 5D).

[A13] The wide bandgap semiconductor device (1A to 1L) according to A12, wherein the resin side surface (22, 22A to 22D) forms a single ground surface together with the side surface (5, 5A to 5D) of the chip (2).

[A14] The wide bandgap semiconductor device (1A to 1L) according to any one of A1 to A13, wherein the thermosetting resin (19) includes a portion directly covering the main surface (3) at a peripheral edge portion of the chip (2).

[A15] The wide bandgap semiconductor device (1A to 1L) according to any one of A1 to A14, wherein the first main surface electrodes (11, 65, 67) are arranged on the main surface, and the thermosetting resin (19) covers the main surface (3) such as to expose a part of each of the first main surface electrodes (11, 65, 67).

[A16] The wide bandgap semiconductor device (1A to 1L) according to any one of A1 to A15, wherein the chip (2) has a laminated structure including a semiconductor substrate (6) and an epitaxial layer (7) that are each composed of a wide bandgap semiconductor, and the chip (2) includes the main surface (3) formed by the epitaxial layer (7).

[A17] The wide bandgap semiconductor device (1A to 1L) according to any one of A1 to A15, wherein the chip (2) has a single layer structure constituted of an epitaxial layer (7) composed of a wide bandgap semiconductor.

[A18] The wide bandgap semiconductor device (1A to 1L) according to any one of A1 to A17 further comprising: a functional device formed at the chip (2); wherein the first main surface electrode (11, 65, 67) is electrically connected to the functional device.

[A19] The wide bandgap semiconductor device (1A to 1L) according to A18, wherein the functional device includes at least either one of a diode (SBD) and a transistor (MISFET).

[A20] A semiconductor package (101A to 101C) comprising: a package main body (102, 122) constituted of a molded resin; a conductive plate (106, 126) arranged in the package main body (102, 122); a terminal electrode (109, 130, 134) arranged in the package main body (102, 122) at an interval from the conductive plate (106, 126) such as to be partially exposed from the package main body (102, 122); the wide bandgap semiconductor device (1A to 1L) according to any one of A1 to A19 arranged on the conductive plate (106, 126) in the package main body (102, 122); and a conductive connecting member (112, 137, 138, 140) electrically connected to the terminal electrode (109, 130, 134) and to the wide bandgap semiconductor device (1A to 1L) in the package main body (102, 122).

[B1] A semiconductor device (1A to 1L) comprising: a chip (2) having a main surface (3); a first main surface electrode (11, 65, 67) arranged on the main surface (3); a first organic film (17) covering a peripheral edge portion of the first main surface electrode (11, 65, 67); and a second organic film (19) that includes a matrix resin (27) and a plurality of fillers (28) and that covers the main surface (3) and the first organic film (17) such as to expose a part of the first main surface electrode (11, 65, 67).

[B2] The semiconductor device (1A to 1L) according to B1, wherein the second organic film (19) includes the fillers (28) that differ from each other in particle size.

[B3] The semiconductor device (1A to 1L) according to B1 or B2, wherein the fillers (28) include a plurality of filler fragments (29, 29a, 29b) that have particle shapes broken in a surface layer portion of the second organic film (19).

[B4] The semiconductor device (1A to 1L) according to any one of B1 to B3, wherein the second organic film (19) is thicker than the first organic film (17).

[B5] The semiconductor device (1A to 1L) according to B4, wherein the fillers (28) include a plurality of small size fillers (28a) thinner than the first main surface electrode (11, 65, 67) and a plurality of large size fillers (28c) thicker than the second organic film (19).

[B6] The semiconductor device (1A to 1L) according to any one of B1 to B5, wherein the first organic film (17) is thicker than the first main surface electrode (11, 65, 67).

[B7] The semiconductor device (1A to 1L) according to any one of B1 to B6, further comprising: a pad electrode (30, 80, 81) arranged on a part of the first main surface electrode (11, 65, 67) which is exposed from the second organic film (19).

[B8] The semiconductor device (1A to 1L) according to B7, wherein the second organic film (19) has an opening (23, 75, 76) defined by a wall surface positioned on the first organic film (17), and the pad electrode (30, 80, 81) is in contact with the first organic film (17) and with the second organic film (19) in the opening (23, 75, 76).

[B9] The semiconductor device (1A to 1L) according to B8, wherein the wall surface of the opening (23, 75, 76) has a lower end portion that forms a gap (24) with an outside surface of the first organic film (17), and the pad electrode (30, 80, 81) has an overhanging portion (30b) that is positioned in the gap (24) and rides on the outside surface of the first organic film (17).

[B10] The semiconductor device (1A to 1L) according to B9, wherein the wall surface of the opening (23, 75, 76) has a first wall portion (25) extending in a thickness direction from an opening end to the lower end portion and a second wall portion (26) extending in a direction intersecting the first wall portion (25) such as to form the gap (24) with the outside surface of the first organic film (17) at the lower end portion.

[B11] The semiconductor device (1A to 1L) according to B9 or B10, wherein a length of the overhanging portion (30b) exceeds a thickness of the first organic film (17).

[B12] The semiconductor device (1A to 1L) according to any one of B9 to B11, wherein the pad electrode (30, 80, 81) has a laminated structure including a first electrode film (31) covering the first main surface electrode (11, 65, 67) and a second electrode film (32) covering the first electrode film (31), and the overhanging portion (30b) includes the first electrode film (31) and the second electrode film (32).

[B13] The semiconductor device (1A to 1L) according to any one of B7 to B12, wherein the pad electrode (30, 80, 81) forms a void space (33) smaller than a thickness of the first main surface electrode (11, 65, 67) at a connection portion with the first main surface electrode (11, 65, 67).

[B14] The semiconductor device (1A to 1L) according to B13, wherein the void space (33) is equal to or less than 1 μm.

[B15] The semiconductor device (1A to 1L) according to any one of B7 to B14, wherein the pad electrode (30, 80, 81) has an electrode surface (30a, 80a, 81a) that forms a single flat surface together with an outside surface of the second organic film (19).

[B16] The semiconductor device (1A to 1L) according to any one of B1 to B15, wherein the chip (2) has a side surface (5, 5A to 5D), and the second organic film (19) has an organic side surface (23, 23A to 23D) that forms a single flat surface together with the side surface (5, 5A to 5D) of the chip (2).

[B17] The semiconductor device (1A to 1L) according to any one of B1 to B16, wherein the chip (2) has a second main surface (4) that faces away from the main surface (3) and that is constituted of a ground surface.

[B18] The semiconductor device (1A to 1F) according to any one of B1 to B17 including the single first main surface electrode (11).

[B19] The semiconductor device (1A to 1F) according to B18, wherein the first main surface electrode (11) forms a Schottky junction with the main surface (3).

[B20] The semiconductor device (1G to 1L) according to any one of B1 to B17 including the first main surface electrodes (11, 65, 66), wherein the first organic film (17) covers a peripheral edge portion of each of the first main surface electrodes (11, 65, 66), and the second organic film (19) covers the main surface (3) such as to expose a part of each of the first main surface electrodes (11, 65, 66).

[B21] The semiconductor device (1G to 1L) according to B20 further comprising: a channel (CH) formed at a surface layer portion of the main surface (3); and a gate structure (50) formed at the main surface (3) such as to control the channel (CH); wherein the first main surface electrodes (11, 65, 66) include a gate main surface electrode (11, 65) electrically connected to the gate structure (50) and a channel main surface electrode (11, 66) electrically connected to the channel (CH).

Although the embodiments have been described in detail, these are merely concrete examples used to clarify the technical contents, and the present invention should not be understood by being limited to these concrete examples, and the scope of the present invention is limited by the appended claims.

### REFERENCE SIGNS LIST

1A wide bandgap semiconductor device
1B wide bandgap semiconductor device
1C wide bandgap semiconductor device
1D wide bandgap semiconductor device
1E wide bandgap semiconductor device
1F wide bandgap semiconductor device
1G wide bandgap semiconductor device
1H wide bandgap semiconductor device
1I wide bandgap semiconductor device
1J wide bandgap semiconductor device
1K wide bandgap semiconductor device
1L wide bandgap semiconductor device
2 chip
3 first main surface
4 second main surface
5 side surface
6 first semiconductor region (semiconductor substrate)
7 second semiconductor region (epitaxial layer)
11 first main surface electrode
17 photosensitive resin
19 thermosetting resin
20 pad opening
21 resin main surface
23 resin side surface
27 matrix resin
28 filler
28a small size filler
28b intermediate size filler
28c large size filler
29 filler fragment
29a first filler fragment
29b second filler fragment
30 pad electrode
30a electrode surface
31 first pad electrode film
32 second pad electrode film
65 gate main surface electrode (first main surface electrode)
67 source main surface electrode (first main surface electrode)
73 gate pad opening (pad opening)
74 source pad opening (pad opening)
80 gate pad electrode (pad electrode)
80a electrode surface
81 source pad electrode (pad electrode)
81a electrode surface
101A semiconductor package
101B semiconductor package
101C semiconductor package
102 package main body
106 metal plate (conductive plate)
109 terminal electrode
112 lead wire (conductive connecting member)
122 package main body
126 first metal plate (conductive plate, terminal electrode)
130 second metal plate (conductive plate, terminal electrode)
134 terminal electrode
137 first conductor spacer (conductive connecting member)
138 second conductor spacer (conductive connecting member)
139 lead wire (conductive connecting member)

1. A wide bandgap semiconductor device comprising:
a chip that includes a wide bandgap semiconductor and that has a main surface;
a main surface electrode arranged on the main surface; and
a thermosetting resin that includes a matrix resin and a plurality of fillers and that covers the main surface such as to expose a part of the main surface electrode.

2. The wide bandgap semiconductor device according to claim 1, wherein the thermosetting resin is thicker than the main surface electrode.

3. The wide bandgap semiconductor device according to claim 1,
wherein the fillers include a plurality of first fillers that are thinner than the main surface electrode and a plurality of second fillers that are thicker than the main surface electrode.

4. The wide bandgap semiconductor device according to claim 1 further comprising:
a photosensitive resin covering a peripheral edge portion of the main surface electrode;
wherein the thermosetting resin covers the photosensitive resin.

5. The wide bandgap semiconductor device according to claim 4,
wherein the photosensitive resin is thicker than the main surface electrode, and
the thermosetting resin is thicker than the photosensitive resin.

6. The wide bandgap semiconductor device according to claim 5,
wherein the fillers include a plurality of large size fillers that are thicker than the photosensitive resin.

7. The wide bandgap semiconductor device according to claim 1,
wherein the thermosetting resin is thicker than the chip.

8. The wide bandgap semiconductor device according to claim 1, further comprising:
a pad electrode that is formed on a part of the main surface electrode which is exposed from the thermosetting resin, and that has an electrode surface exposed from the thermosetting resin.

9. The wide bandgap semiconductor device according to claim 8,
wherein the electrode surface forms a single flat surface together with an outside surface of the thermosetting resin.

10. The wide bandgap semiconductor device according to claim 8,
wherein the pad electrode has a laminated structure including a first electrode film covering the main surface electrode and a second electrode film covering the first electrode film.

11. The wide bandgap semiconductor device according to claim 1,
wherein the fillers include a plurality of filler fragments having particle shapes broken in a surface layer portion of the thermosetting resin.

12. The wide bandgap semiconductor device according to claim 1,
wherein the chip has a side surface, and
the thermosetting resin has a resin side surface continuous to the side surface.

13. The wide bandgap semiconductor device according to claim 12,
wherein the resin side surface forms a single ground surface together with the side surface of the chip.

14. The wide bandgap semiconductor device according to claim 1,
wherein the thermosetting resin includes a portion directly covering the main surface at a peripheral edge portion of the chip.

15. The wide bandgap semiconductor device according to claim 1,
wherein the main surface electrodes are arranged on the main surface, and
the thermosetting resin covers the main surface such as to expose a part of each of the main surface electrodes.

16. The wide bandgap semiconductor device according to claim 1,
wherein the chip has a laminated structure including a semiconductor substrate and an epitaxial layer that are each composed of a wide bandgap semiconductor, and the chip includes the main surface formed by the epitaxial layer.

17. The wide bandgap semiconductor device according to claim 1,
wherein the chip has a single layer structure constituted of an epitaxial layer.

18. The wide bandgap semiconductor device according to claim 1 further comprising:
a functional device formed at the chip;
wherein the main surface electrode is electrically connected to the functional device.

19. The wide bandgap semiconductor device according to claim 18,
wherein the functional device includes at least either one of a diode and a transistor.

20. A semiconductor package comprising:
a package main body constituted of a molded resin;
a conductive plate arranged in the package main body;
a terminal electrode arranged in the package main body at an interval from the conductive plate such as to be partially exposed from the package main body;
the wide bandgap semiconductor device according to claim 1 arranged on the conductive plate in the package main body; and
a connecting member electrically connected to the terminal electrode and to the wide bandgap semiconductor device in the package main body.
